(19) United States
(12) Patent Application Publication
(10) Pub. No.: US 2024/0268115 A1
(43) Pub. Date: Aug. 8, 2024

(54) THREE-DIMENSIONAL MEMORY DEVICE CONTAINING HETEROJUNCTION SOURCE LAYER AND METHOD FOR MANUFACTURING THE SAME

(71) Applicant: SANDISK TECHNOLOGIES LLC, ADDISON, TX (US)

(72) Inventors: Wei CAO, Milpitas, CA (US); Xiang YANG, Santa Clara, CA (US); Koichi MATSUNO, Fremont, CA (US)

(21) Appl. No.: 18/357,702

(22) Filed: Jul. 24, 2023

Related U.S. Application Data
(60) Provisional application No. 63/483,339, filed on Feb. 6, 2023.

(51) Int. Cl. H10B 43/27; H01L 23/00; H01L 25/00; H01L 25/065; H01L 25/18; H10B 43/35; H10B 80/00

(52) U.S. Cl. CPC H10B 43/27; H01L 24/08; H01L 24/80; H01L 25/0657; H01L 25/18; H01L 25/50; H10B 43/35; H10B 80/00; H01L 2224/08145; H01L 2224/80006; H01L 2224/80895; H01L 2224/80896; H01L 2924/1431; H01L 2924/14511

(57) ABSTRACT

A memory device includes an alternating stack of insulating layers and electrically conductive layers, a memory opening vertically extending through the alternating stack, a memory opening fill structure located in the memory opening and including a memory film and a vertical semiconductor channel including a first semiconductor material, and source structure including an interfacial source layer and a primary source layer. The interfacial source layer includes a second semiconductor material that has a different band gap from a band gap of the first semiconductor material and is in contact with an end portion of the vertical semiconductor channel. The primary source layer includes a third semiconductor material that has a different band gap from the band gap of the second semiconductor material, and the primary source layer is in contact with the interfacial source layer.

### FIELD

The present disclosure relates generally to the field of semiconductor devices, and particularly to a three-dimensional memory device including a heterojunction source layer and method for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device is provided, which comprises: an alternating stack of insulating layers and electrically conductive layers; a memory opening vertically extending through the alternating stack; a memory opening fill structure located in the memory opening and comprising a memory film and a vertical semiconductor channel comprising a first semiconductor material; and a source structure comprising an interfacial source layer and a primary source layer, wherein the interfacial source layer comprises a second semiconductor material that has a different band gap from a band gap of the first semiconductor material and is in contact with an end portion of the vertical semiconductor channel, and the primary source layer comprises a third semiconductor material that has a different band gap from the band gap of the second semiconductor material, and the primary source layer is in contact with the interfacial source layer.

According to another aspect of the present disclosure, a method of forming a memory device is provided. The method comprises: forming an alternating stack of insulating layers and spacer material layers over a carrier substrate, wherein the spacer material layers are formed as, or are subsequently replaced with, electrically conductive layers; forming a memory opening through the alternating stack; forming a memory opening fill structure in the memory opening, wherein the memory opening fill structure comprises a memory film and a vertical semiconductor channel comprising a first semiconductor material having a first band gap; removing the carrier substrate; forming a cavity within a volume of the memory opening and exposing a surface of the vertical semiconductor channel from a side of the memory opening from which the carrier substrate is removed; forming an interfacial source layer comprising a second semiconductor material having a second band gap that is different from the first band gap on an end portion of the vertical semiconductor channel at least in a first portion of the cavity; and forming a primary source layer comprising a third semiconductor material having a third band gap that is different from the second band gap on the interfacial source layer.

### BRIEF DESCRIPTION OF THE DRAWINGS

FIG. 1 is a schematic vertical cross-sectional view of a first exemplary structure after formation of an alternating stack of insulating layers and sacrificial material layers and first dielectric material portions over a carrier substrate according to a first embodiment of the present disclosure.

FIG. 2 is a schematic vertical cross-sectional view of the first exemplary structure after patterning the alternating stack and formation of dielectric material portions according to the first embodiment of the present disclosure.

FIG. 3A is a schematic vertical cross-sectional view of the first exemplary structure after formation of memory openings according to the first embodiment of the present disclosure.

FIG. 3B is a top-down view of the first exemplary structure of FIG. 3A. The vertical plane A-A′ is the cut plane of the vertical cross-sectional view of FIG. 3A.

FIGS. 4A-4D are sequential vertical cross-sectional views of a memory opening during formation of a memory opening fill structure according to the first embodiments of the present disclosure.

FIG. 5A is a vertical cross-sectional view of the first exemplary structure after formation of memory opening fill structures according to the first embodiment of the present disclosure.

FIG. 5B is a top-down view of the first exemplary structure of FIG. 5A. The vertical plane A-A′ is the cut plane of the vertical cross-sectional view of FIG. 5A.

FIG. 6A is a vertical cross-sectional view of the first exemplary structure after formation of lateral isolation trenches according to the first embodiment of the present disclosure.

FIG. 6B is a top-down view of the first exemplary structure of FIG. 6A. The vertical plane A-A′ is the cut plane of the vertical cross-sectional view of FIG. 6A.

FIG. 7 is a vertical cross-sectional view of the first exemplary structure after formation of lateral recesses according to the first embodiment of the present disclosure.

FIG. 8 is a vertical cross-sectional view of the first exemplary structure after formation of electrically conductive layers according to the first embodiment of the present disclosure.

FIG. 9 is a vertical cross-sectional view of the first exemplary structure after formation of lateral isolation trench fill structures according to the first embodiment of the present disclosure.

FIG. 10A is a vertical cross-sectional view of the first exemplary structure after formation of contact via structures according to the first embodiment of the present disclosure.

FIG. 10B is a top-down view of the first exemplary structure of FIG. 10A. The vertical plane A-A′ is the cut plane of the vertical cross-sectional view of FIG. 10A.

FIG. 11A is a vertical cross-sectional view of the first exemplary structure after formation of connection via structures and first-level metal lines including bit lines according to the first embodiment of the present disclosure.

FIG. 11B is a top-down view of the first exemplary structure of FIG. 11A. The vertical plane A-A′ is the cut plane of the vertical cross-sectional view of FIG. 11A.

FIG. 12 is a vertical cross-sectional view of the first exemplary structure after formation of a memory die and attachment of a logic die to the memory die according to the first embodiment of the present disclosure.

FIG. 13A is a vertical cross-sectional view of the first exemplary structure after removal of the carrier substrate according to the first embodiment of the present disclosure.

FIG. 13B is a magnified view of region B in the first exemplary structure of FIG. 13A.

FIGS. 14A-14C are sequential vertical cross-sectional views of a region of the first exemplary structure during formation of an interfacial source layer and a primary source layer according to the first embodiment of the present disclosure.

FIG. 15 is a vertical cross-sectional view of the first exemplary structure after patterning the interfacial source layer and the primary source layer and formation of at least one backside dielectric layer and backside bonding pads according to the first embodiment of the present disclosure.

FIGS. 16A-16E are sequential vertical cross-sectional views of a region of a second exemplary structure during formation of an interfacial source layer and a primary source layer according to a second embodiment of the present disclosure.

FIG. 17 is a vertical cross-sectional view of the second exemplary structure after patterning the interfacial source layer and the primary source layer and formation of at least one backside dielectric layer and backside bonding pads according to the second embodiment of the present disclosure.

FIGS. 18A-18F are vertical cross-sectional views of a memory opening in a third exemplary structure during formation of a memory opening fill structure according to a third embodiment of the present disclosure.

FIG. 19A is a vertical cross-sectional view of a third exemplary structure after removal of the carrier substrate according to the third embodiment of the present disclosure.

FIG. 19B is a magnified view of region B in the third exemplary structure of FIG. 19A.

FIGS. 20A and 20B are sequential vertical cross-sectional views of a region of the third exemplary structure during formation of an interfacial source layer and a primary source layer according to the third embodiment of the present disclosure.

FIG. 21 is a vertical cross-sectional view of the third exemplary structure after patterning the interfacial source layer and the primary source layer and formation of at least one backside dielectric layer and backside bonding pads according to the third embodiment of the present disclosure.

FIG. 22 illustrates band diagrams of a comparative exemplary structure in which only silicon is employed within a source structure during various operational modes.

FIG. 23 illustrates band diagrams of the first exemplary structure according to the first embodiment of the present disclosure during various operational modes.

FIG. 24 illustrates band diagrams of the second exemplary structure according to the second embodiment of the present disclosure during various operational modes.

FIG. 25 illustrates a band diagram of the third exemplary structure according to the third embodiment of the present disclosure during hole injection.

FIGS. 26A-26J are sequential vertical cross-sectional views of a region of a fourth exemplary structure during formation of a source structure according to a fourth embodiment of the present disclosure.

### DETAILED DESCRIPTION

As discussed above, the present disclosure is directed to a three-dimensional memory device including a heterojunction source layer, and methods of employing the same, the various aspects of which are described below. Embodiments of the disclosure can be employed to form various structures including a multilevel memory structure, non-limiting examples of which include three-dimensional memory array devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

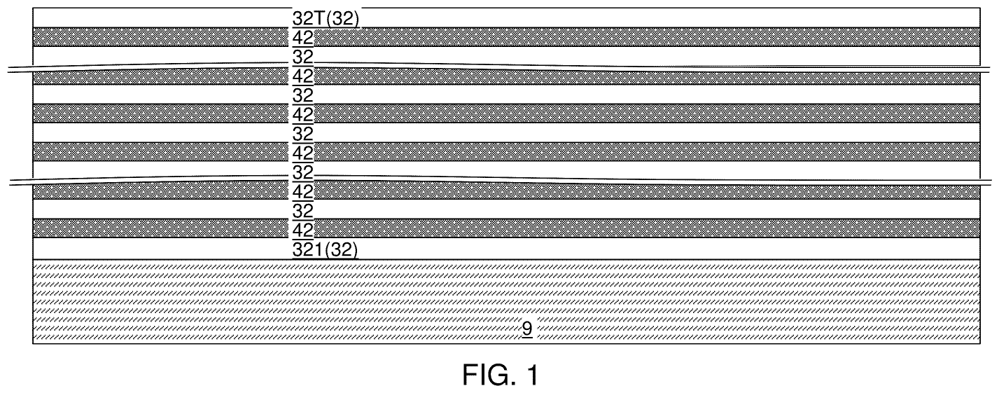

Referring to FIG. 1, an exemplary structure according to an embodiment of the present disclosure is illustrated. The exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed.

An alternating stack of insulating layers 32 and spacer material layers can be formed over the carrier substrate 9. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 or to backside structures to be subsequently formed in lieu of the carrier substrate 9, and may be referred to as a most proximal insulating layer 321.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

While an embodiment is described in which the spacer material layers are formed as sacrificial material layers 42, the spacer material layers may be formed as first electrically conductive layers in an alternative embodiment. Generally, spacer material layers may be formed as or may be subsequently replaced at least partly with electrically conductive layers.

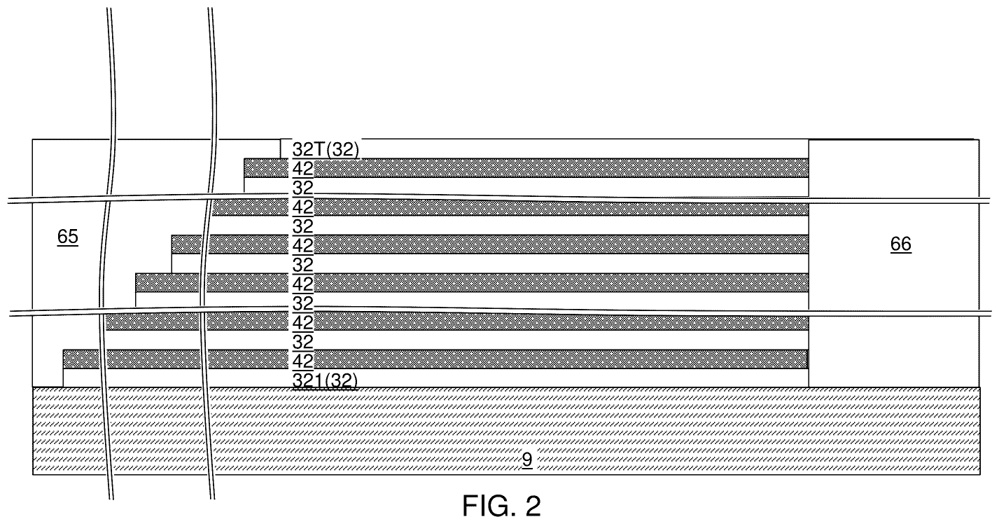

Referring to FIG. 2, stepped surfaces may be formed by patterning one side of the alternating stack (32, 42). Another side of the alternating stack (32, 42) may be optionally removed to provide a straight sidewall that extends from a bottommost surface to a topmost surface of the alternating stack (32, 42). A dielectric fill material such as undoped silicate glass or a doped silicate glass can be deposited over the alternating stack (32, 42), and excess portions of the dielectric fill material may be removed from above the horizontal plane including the top surface of the topmost insulating layer 32 by a planarization process, which may employ a chemical mechanical polishing process and/or a recess etch process. A retro-stepped dielectric material portion 65 may be formed over the stepped surfaces. A field dielectric material portion 66 may be formed over a top surface of the carrier substrate 9 adjacent to a straight sidewall of the alternating stack (32, 42). The retro-stepped dielectric material portion 65 and the field dielectric material portion 66 are herein collectively referred to as dielectric material portions (65, 66).

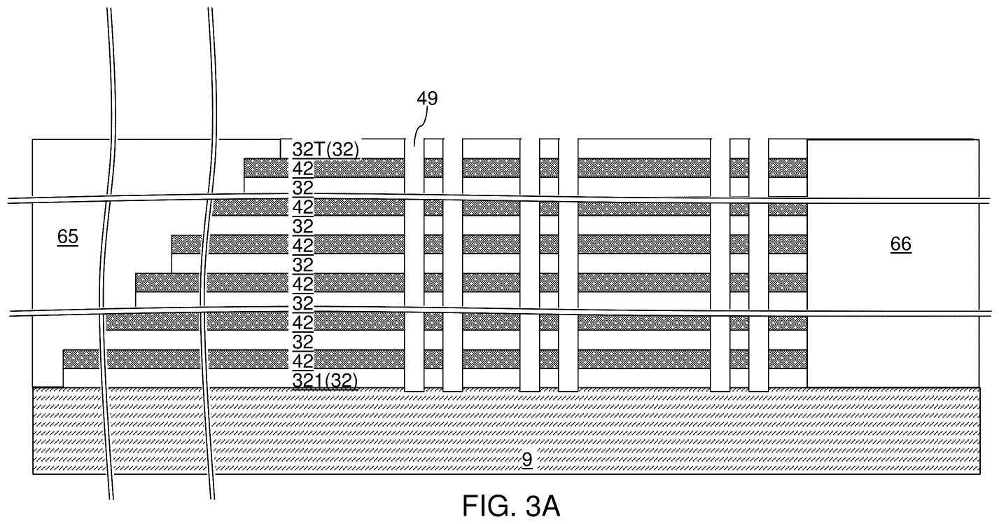

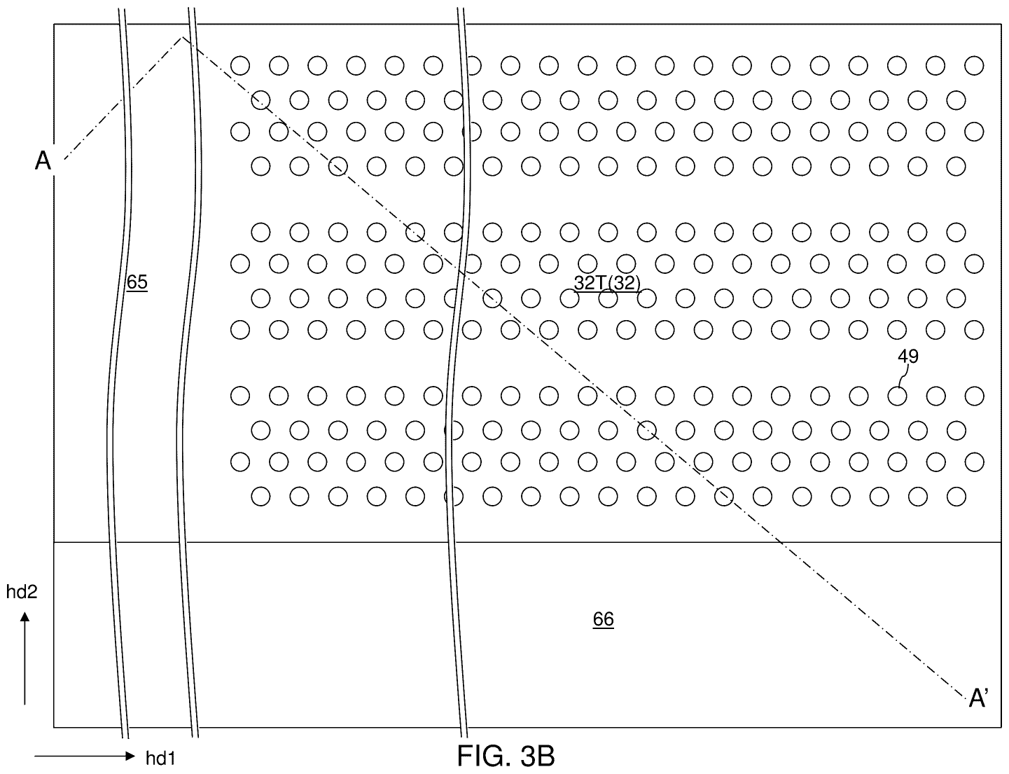

Referring to FIGS. 3A and 3B, an etch mask layer (not shown) can be formed over the alternating stack (32, 42), and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that vertically extend through each layer within the alternating stack (32, 42), and additional openings such as support openings (not illustrated) that are formed in the stepped surface area and subsequently employed to form support pillar structures. In one embodiment, the memory openings 49 may be formed in rows that laterally extend along a first horizontal direction hd1. The rows of memory openings 49 may be arranged along a second horizontal direction hd2 that is perpendicular to the first horizontal direction hd1. The etch mask layer can be subsequently removed.

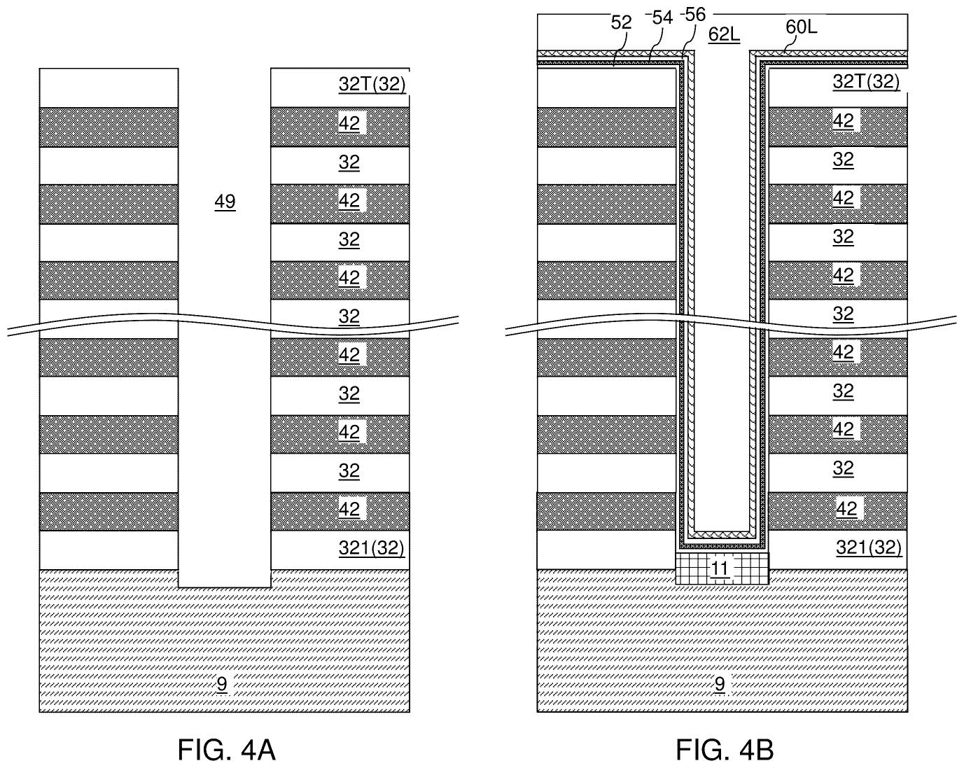

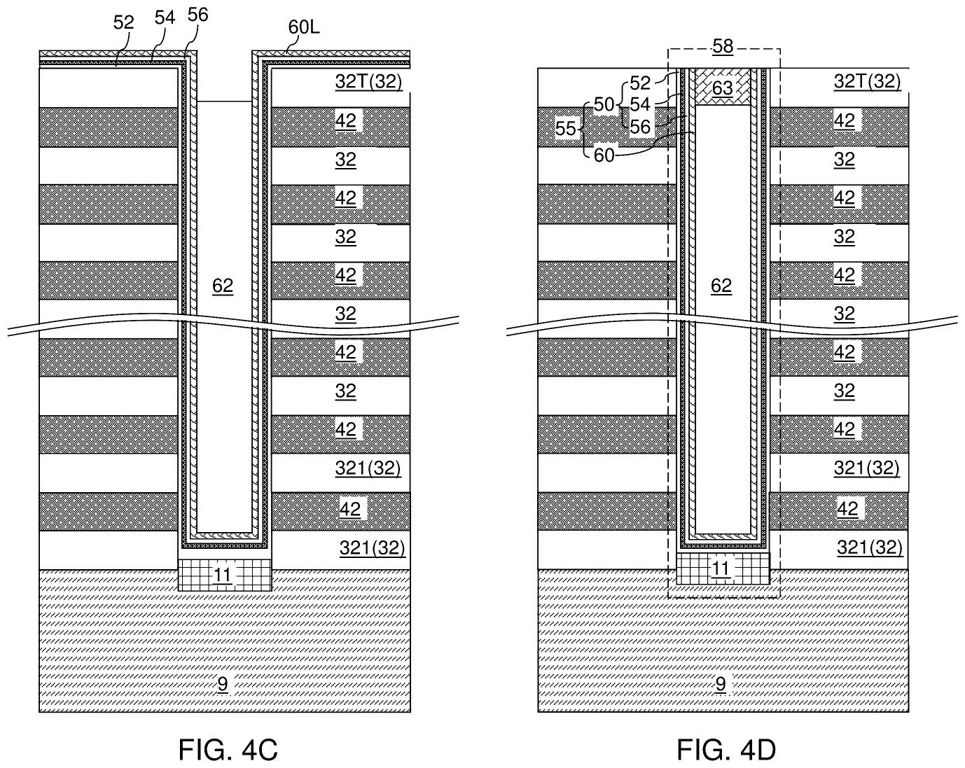

FIGS. 4A-4D are sequential vertical cross-sectional views of a memory opening 49 during formation of a memory opening fill structure 58 according to the first embodiments of the present disclosure.

Referring to FIG. 4A, a memory opening 49 is illustrated after the processing steps of FIGS. 3A and 3B.

Referring to FIG. 4B, sacrificial pillar structures 11 can be formed at the bottom of the memory openings 49. The sacrificial pillar structures 11 may comprise a sacrificial material that can be subsequently removed. For example, the sacrificial pillar structures 11 can comprise a semiconductor material (e.g., single crystalline silicon), a carbon-based material (such as amorphous carbon or diamond-like carbon (DLC)), or a high-etch-rate dielectric material, such as borosilicate glass. In case the sacrificial pillar structures 11 comprise a semiconductor material, the sacrificial pillar structures 11 can be formed by selective growth of the semiconductor (e.g., single crystalline silicon) material from physically exposed surfaces of the carrier substrate 9. A selective semiconductor deposition process, such as a selective epitaxy process may be employed to form the sacrificial pillar structures 11.

Subsequently, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. Generally, the first semiconductor channel material layer 60 comprises a first semiconductor material having a first band gap. In one embodiment, the first semiconductor material comprises a first doped silicon material having a doping of the first conductivity type, such as p-type. In an illustrative example, the atomic concentration of dopants (e.g., boron) of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 4C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 4D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a sacrificial pillar structure 11, a memory stack structure 55, a dielectric core 62, and a drain region 63 within a memory opening 49 constitutes a memory opening fill structure 58. Each memory opening fill structure 58 comprises a respective vertical stack of memory elements, which may be embodied as portions of the memory material layer 54 located at levels of the sacrificial material layers 42, or generally speaking, at levels of spacer material layers that may be formed as, or may be subsequently replaced at least partly with, electrically conductive layers.

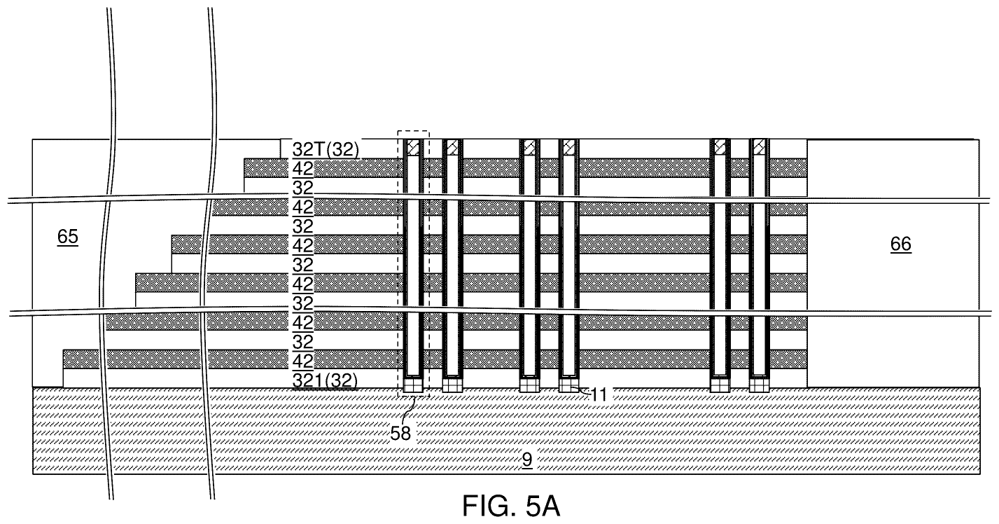

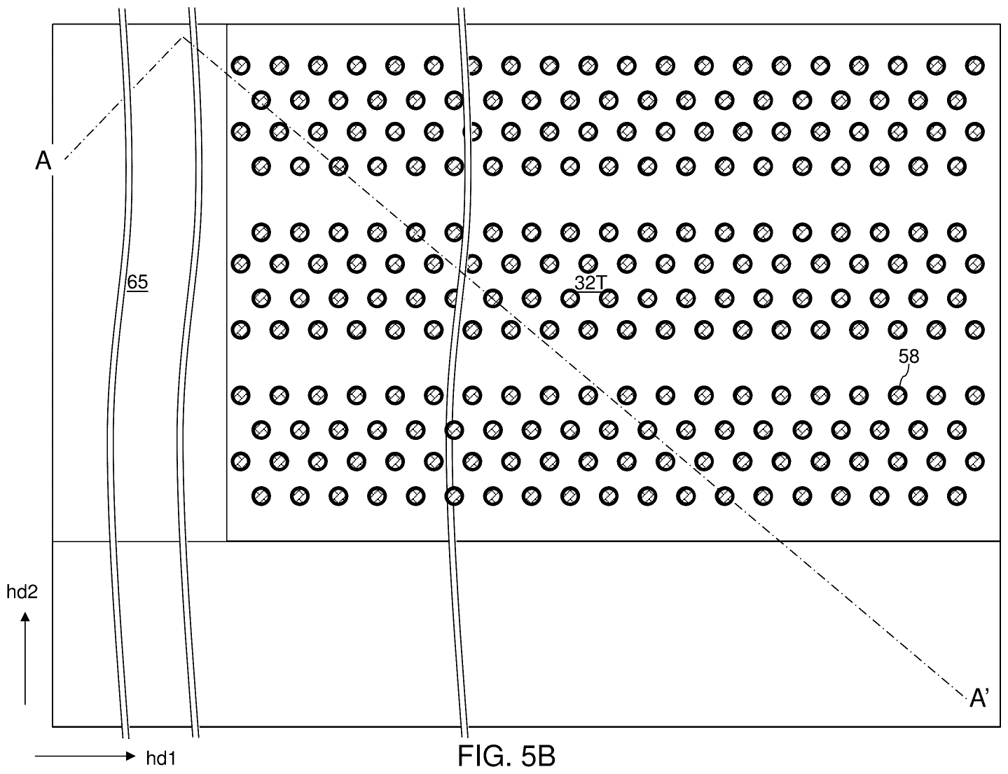

Referring to FIGS. 5A and 5B, the exemplary structure is illustrated after formation of memory opening fill structures 58 within the memory openings 49. Each of the memory opening fill structures 58 may comprise a sacrificial pillar structure 11 on which a memory film 50 and a vertical semiconductor channel 60 are formed. Optionally, support pillar structures (not shown) may be formed in support openings (not shown) through the alternating stack (32, 42) concurrently with formation of the memory opening fill structures 58 such that each of the support pillar structures has a substantially same structure as a memory opening fill structure 58. Alternatively or additionally, dielectric support pillar structures may be formed in support openings through the alternating stack (32, 42) prior to or after formation of the memory opening fill structures 58.

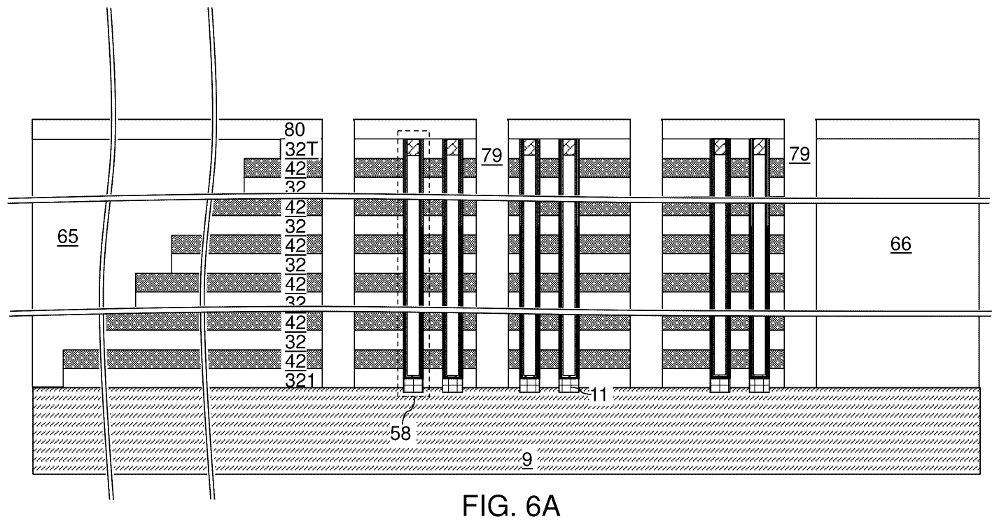

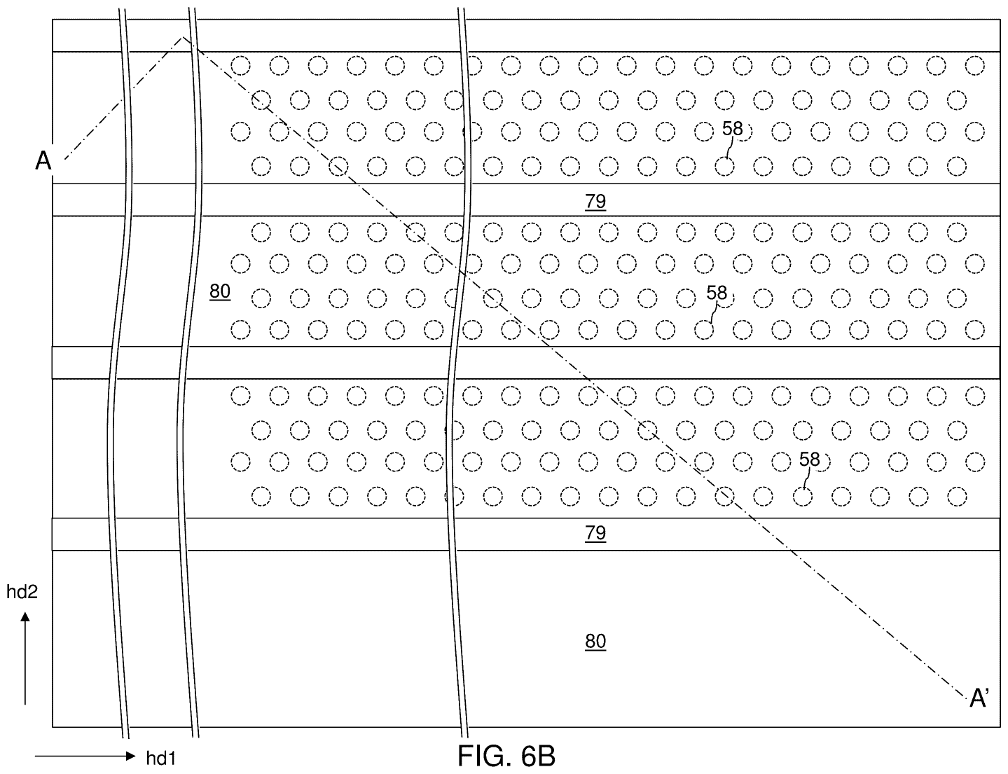

Referring to FIGS. 6A and 6B, a contact-level dielectric layer 80 can be formed over the alternating stack (32, 42). A photoresist layer (not shown) can be applied over the contact-level dielectric layer 80, and can be lithographically patterned to form elongated openings that laterally extend along the first horizontal direction (e.g., word line direction) hd1 between neighboring clusters of memory opening fill structures 58. An anisotropic etch process can be performed to transfer the pattern of the openings in the photoresist layer through the contact-level dielectric layer 80, the alternating stack (32, 42), and the dielectric material portions (65, 66). Lateral isolation trenches 79 laterally extending along the first horizontal direction hd1 can be formed through the alternating stack (32, 42), the dielectric material portions (65, 66), and the contact-level dielectric layer 80. Each of the lateral isolation trenches 79 may comprise a respective pair of lengthwise sidewalls that are parallel to the first horizontal direction hd1 and vertically extend from the carrier substrate 9 to the top surface of the contact-level dielectric layer 80. A top surface of the carrier substrate 9 can be physically exposed underneath each lateral isolation trench 79. The photoresist layer can be subsequently removed, for example, by ashing.

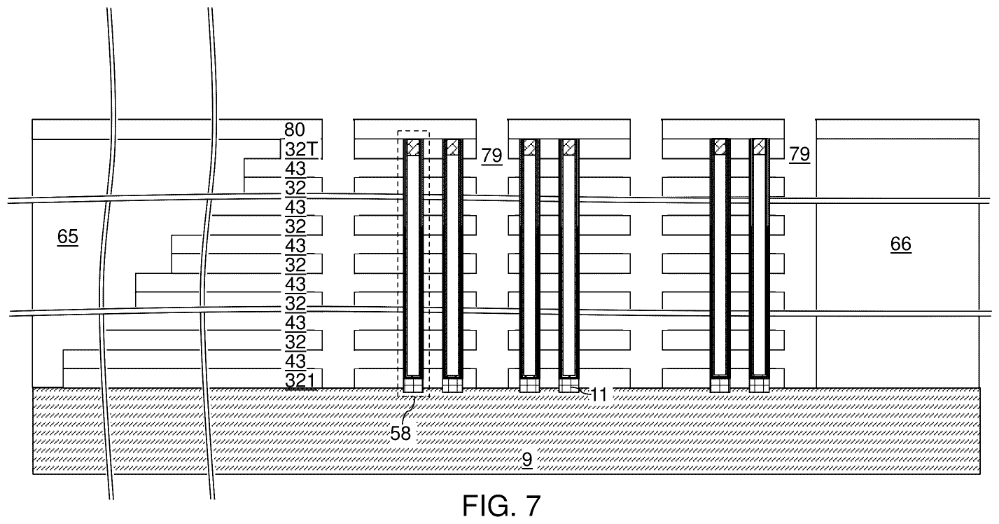

Referring to FIG. 7, an isotropic etch process can be performed to remove the sacrificial material layers 42 selective to the insulating layers 32, the memory opening fill structures 58, and the carrier substrate 9. Lateral recesses 43 can be formed in volumes from which the sacrificial material layers 42 are removed. Sidewall surface segments of the memory opening fill structures 58 can be physically exposed to the lateral recesses 43. In an illustrative example, if the sacrificial material layers 42 comprise silicon nitride, the isotropic etch process may comprise a wet etch process employing hot phosphoric acid.

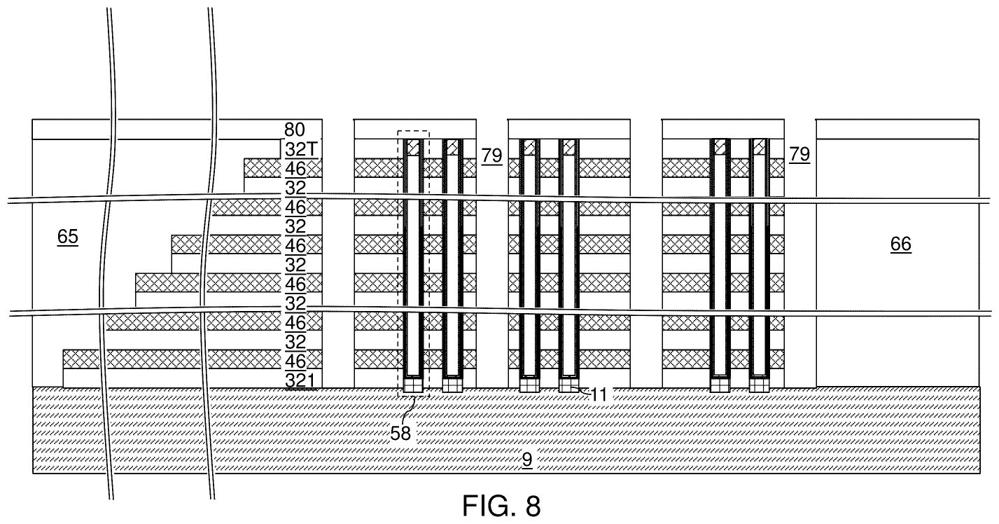

Referring to FIG. 8, a backside blocking dielectric layer (not shown) can be optionally formed in the lateral recesses 43 by a conformal deposition process. At least one conductive material, such as at least one metallic material, can be conformally deposited in the lateral recesses 43. The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the lateral recesses 43 constitutes an electrically conductive layer 46. An alternating stack of insulating layers 32 and electrically conductive layers 46 can be formed between each neighboring pair of lateral isolation trenches 79 over the carrier substrate 8. A plurality of alternating stacks of insulating layers 32 and electrically conductive layers 46 can be laterally spaced apart from each other by the lateral isolation trenches 79.

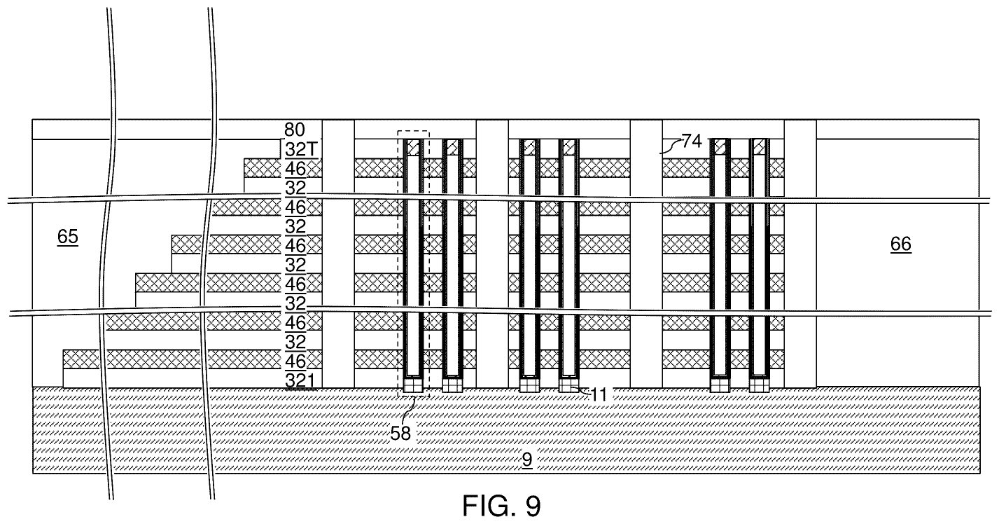

Referring to FIG. 9, an insulating material may be deposited in each of the lateral isolation trenches 79. The insulating material constitutes an isolation trench fill structure 74 that fills a respective lateral isolation trench 79.

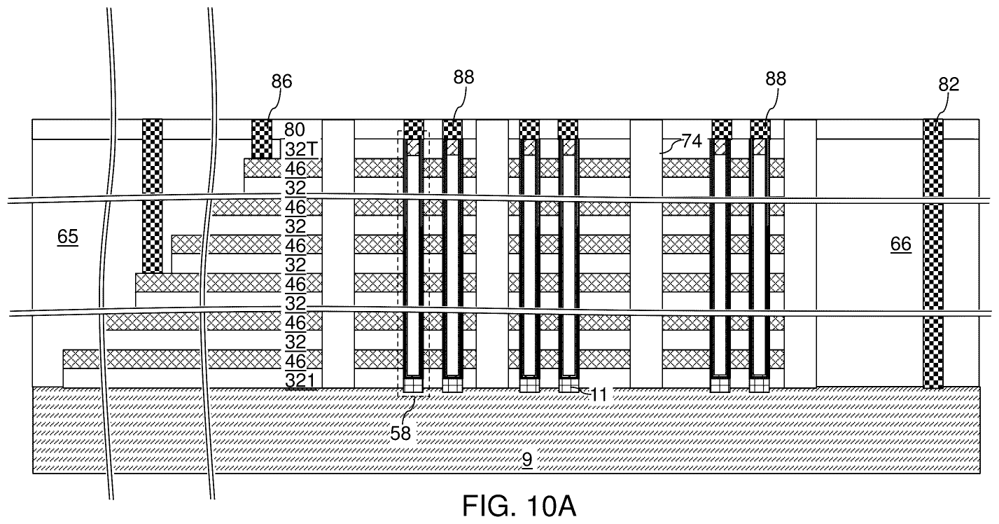

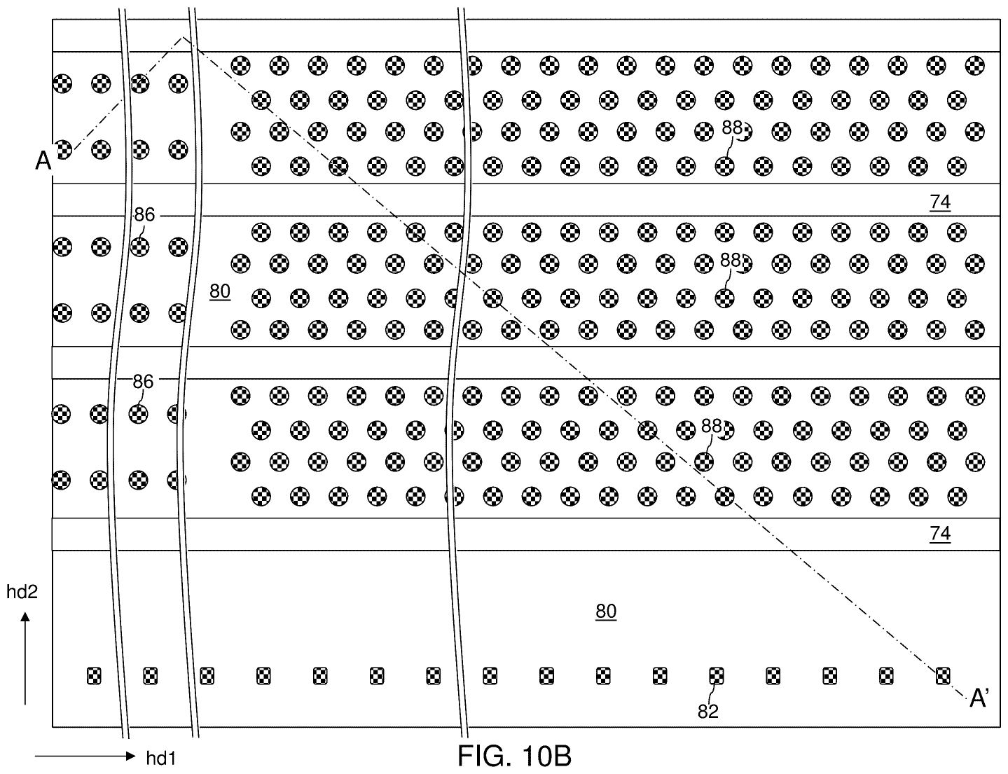

Referring to FIGS. 10A and 10B, a photoresist layer (not shown) can be applied over the contact-level dielectric layer 80, and can be lithographically patterned to form openings therethrough. An anisotropic etch process can be performed to transfer the pattern of the openings in the photoresist layer through the contact-level dielectric layer 80 and optionally through the dielectric material portions (65, 66). Various contact via cavities can be formed through the contact-level dielectric layer 80 and the dielectric material portions (65, 66). The photoresist layer can be subsequently removed, for example, by ashing.

At least one conductive material, such as a combination of a metallic barrier material and a metallic fill material, can be deposited in the contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the various contact via cavities constitute various contact via structures (86, 88, 82). The various contact via structures (86, 88, 82) may comprise layer contact via structures (e.g., word line contact via structures) 86 vertically extending through the contact-level dielectric layer 80 and the retro-stepped dielectric material portion 65 and contacting a respective one of the electrically conductive layers 86, drain contact via structures 88 contacting a top surface of a respective one of the drain regions 63, and through-memory-level via structures 82 that vertically extend through the contact-level dielectric layer 80 and the field dielectric material portion 66 and contacting a top surface of the carrier substrate 9.

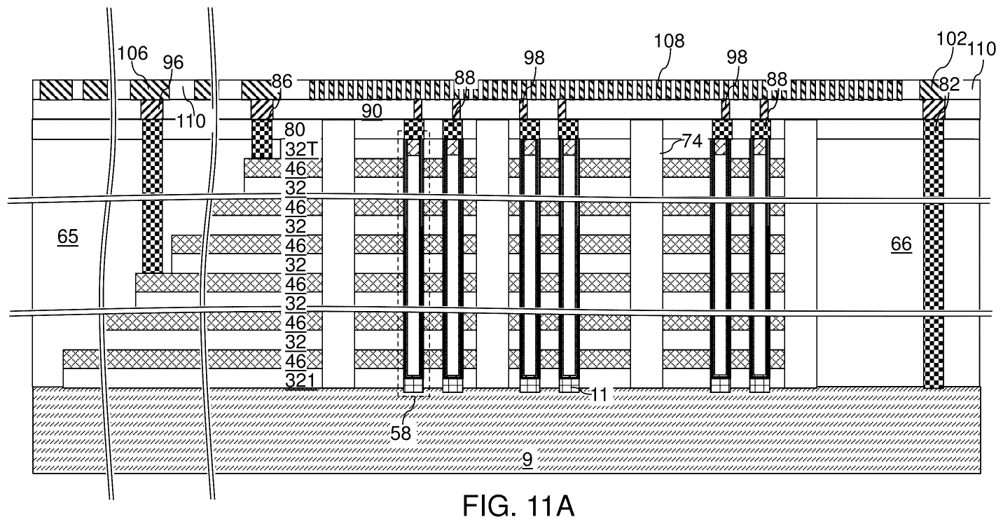

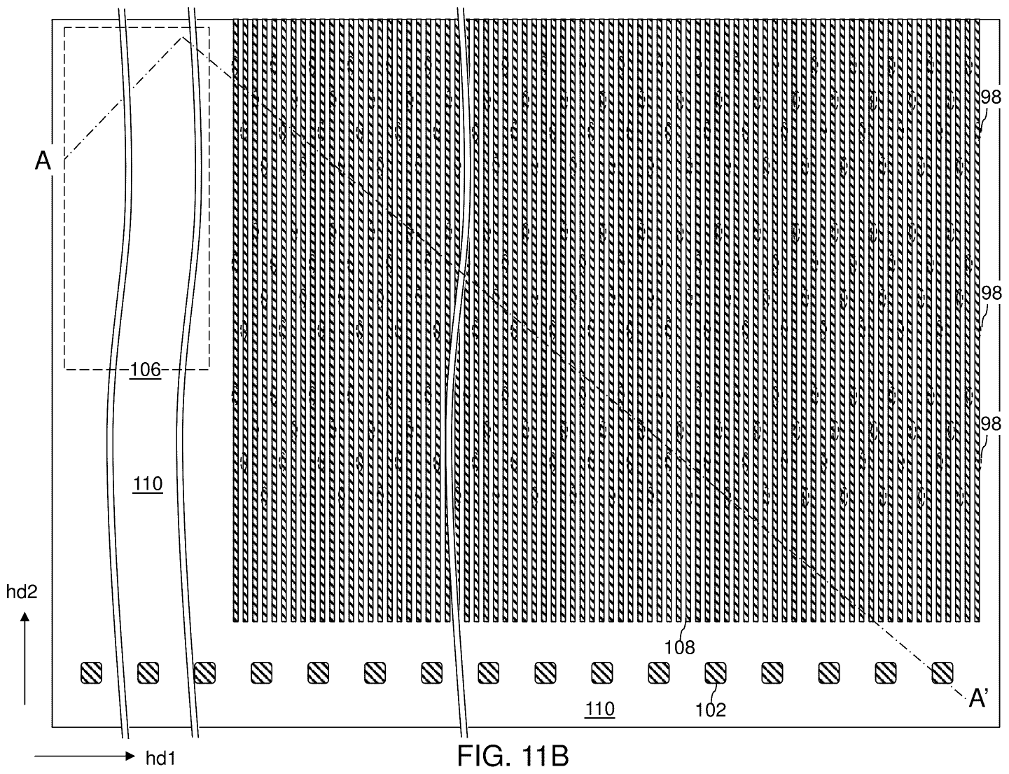

Referring to FIGS. 11A and 11B, a connection-level dielectric layer 90 can be formed over the contact-level dielectric layer 80 by deposition of a dielectric material such as silicon oxide. Connection via structures (98, 96, 92) can be formed through the connection-level dielectric layer 90 on a respective one of the contact via structures (86, 88, 82). For example, bit-line-connection via structures 98 can be formed on the drain contact via structures 88, layer connection via structures 96 can be formed on the layer contact via structures 86, and peripheral connection via structures 92 that are formed on through-memory-level via structures 82. A line-level dielectric layer can be formed over the connection-level dielectric layer 90. The line-level dielectric layer is herein referred to as a bit-line-level dielectric layer 110 or a first-metal-line-level dielectric layer 110. First-level metal lines (108, 106, 102) can be formed in the bit-line-level dielectric layer 110. The first-level metal lines (108, 106, 102) may include bit lines 108, first word-line-connection metal lines 106, and first peripheral-connection metal lines 102. The bit lines 108 can be parallel to each other, and can laterally extend along a horizontal direction that is perpendicular to the lengthwise direction of the isolation trench fill structures 74. For example, if the isolation trench fill structures 74 laterally extend along the first horizontal direction hd1, the bit lines 108 may laterally extend along the second horizontal direction (i.e., bit line direction) hd2. In one embodiment, the bit lines 108 are laterally spaced from each other along the first horizontal direction hd1 with a first pitch and laterally extend along the second horizontal direction hd2.

Each bit line 108 can be electrically connected to a respective subset of the drain regions 63 through a respective subset of the drain contact via structures 88 and a respective subset of the bit-line-connection via structures 98. The first word-line-connection metal lines 106 can be formed on the layer connection via structures 96. The first peripheral-connection metal lines 108 can be formed on the peripheral connection via structures 92.

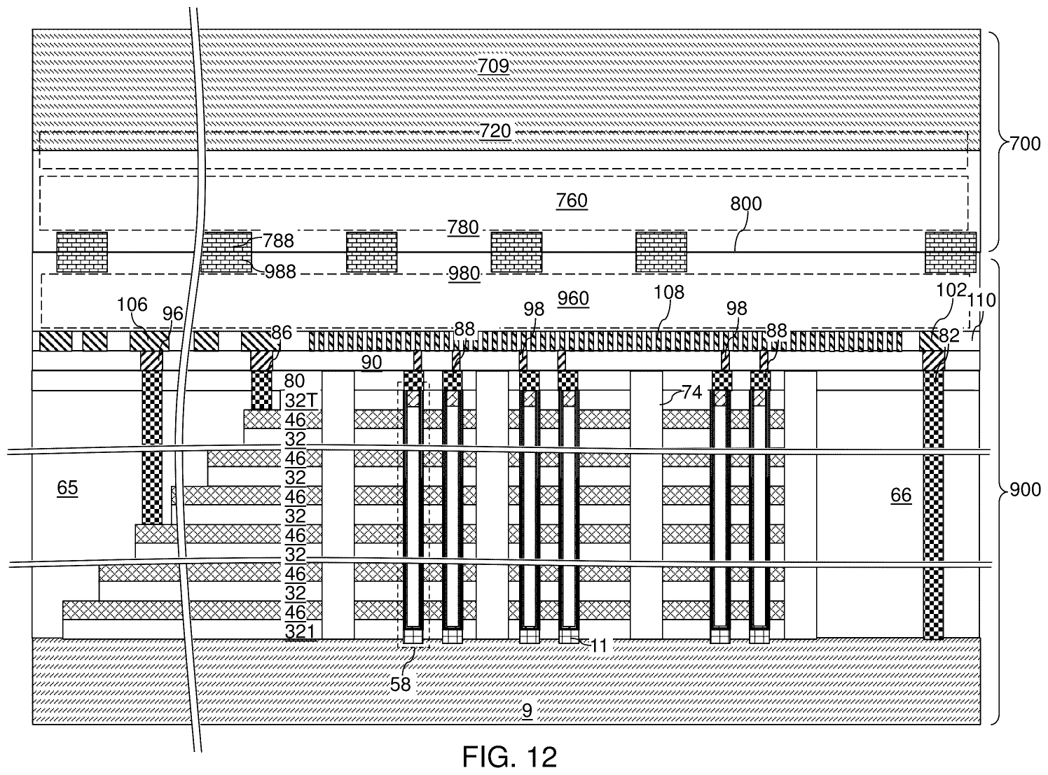

Referring to FIG. 12, additional dielectric material layers 960 and additional metal interconnect structures 980 can be formed over the bit-line-level dielectric layer 110. The additional dielectric material layers may include at least one via-level dielectric layer, at least one additional line-level dielectric layer, and/or at least one additional line-and-via-level dielectric layer. The additional metal interconnect structures 980 may comprise metal via structures, metal line structures, and/or integrated metal line-and-via structures. Metal bonding pads, which are herein referred to as memory-side bonding pads 988, may be formed at the topmost level of the additional dielectric material layers 960. The memory-side bonding pads 988 may be electrically connected to the additional metal interconnect structures 980 and various nodes of the three-dimensional memory array including the alternating stacks of insulating layers 32 and electrically conductive layers 46 and the memory opening fill structures 58. A memory die 900 is thus formed.

The set of all metal interconnect structures formed in, or above, the contact-level dielectric layer 80 is herein referred to as memory-side metal interconnect structures (88, 86, 82, 98, 96, 92, 102, 106, 108, 980). The set of all dielectric material layers formed above the alternating stacks (32, 46) is herein referred to as memory-side dielectric material layers (80, 90, 110, 960). The memory-side dielectric material layers (80, 90, 110, 960) are formed over the alternating stacks (32, 46). The memory-side metal interconnect structures (88, 86, 82, 98, 96, 92, 102, 106, 108, 980) comprise bit lines 108. The memory-side bonding pads 988 can be embedded within the memory-side dielectric material layers (80, 90, 110, 960), and specifically, within the topmost layer among the memory-side dielectric material layers (80, 90, 110, 960). The memory-side bonding pads 988 can be electrically connected to the memory-side metal interconnect structures (88, 86, 82, 98, 96, 92, 102, 106, 108, 980).

Additionally, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 53, and a source structure to be subsequently formed. The peripheral circuit 720 can be configured to control operation of the vertical stack of memory elements in the memory array in the memory die 900.

The logic die 700 can be attached to the memory die 900, for example, by bonding the logic-side bonding pads 778 to the memory-side bonding pads 978. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900 at a bonding interface 800.

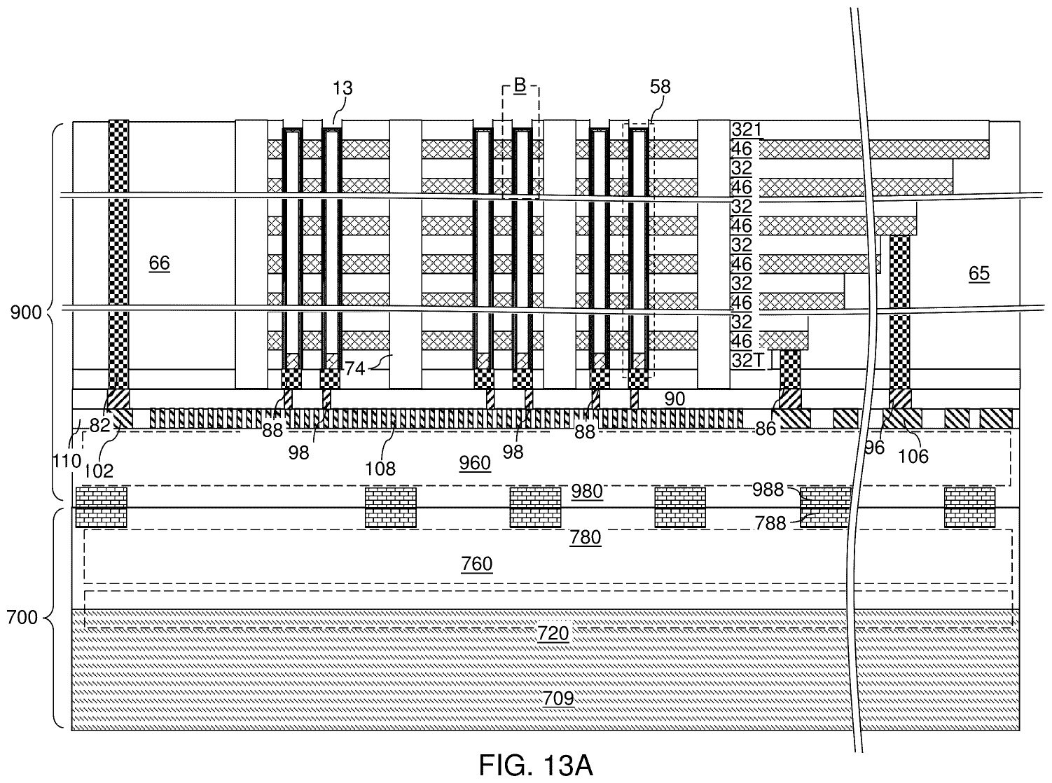

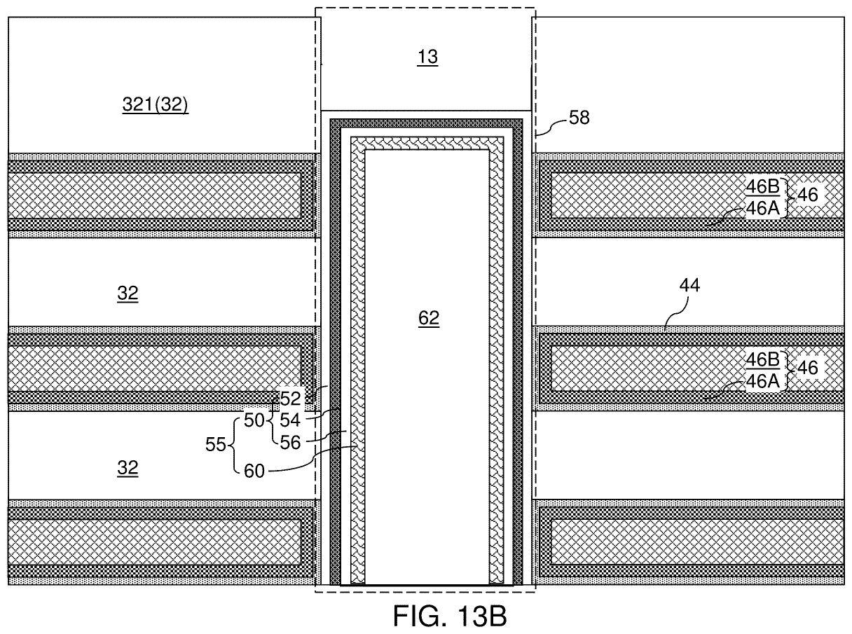

Referring to FIGS. 13A and 13B, the carrier substrate 9 can be removed, for example, by grinding, polishing, cleaving, an isotropic etch process, and/or an anisotropic etch process. The bottom surface of the most proximal insulating layer 321 within each alternating stack (32, 46) of insulating layers 32 and electrically conductive layers 46 can be physically exposed. In case an etch process is employed as a last processing step for removing the carrier substrate 9 selective to the material of the most proximal insulating layer 321 and if the sacrificial pillar structures 11 comprise a semiconductor material, the sacrificial pillar structures 11 can be removed during removal of the carrier substrate 9. Alternatively, a selective etch process can be performed to remove the sacrificial pillar structures 11 selective to the materials of the insulating layers 321 and the memory films 50. A cavity 13 can be formed in each volume from which a sacrificial pillar structure 11 is removed. A bottom surface of a memory film 50 can be physically exposed to a respective cavity 13. FIG. 13B illustrates an embodiment in which each electrically conductive layer 46 comprises a metallic barrier liner 46A and a metallic fill material portion 46B, and is spaced from adjacent insulating layers 32 and memory opening fill structures 58 by a backside blocking dielectric layer 44.

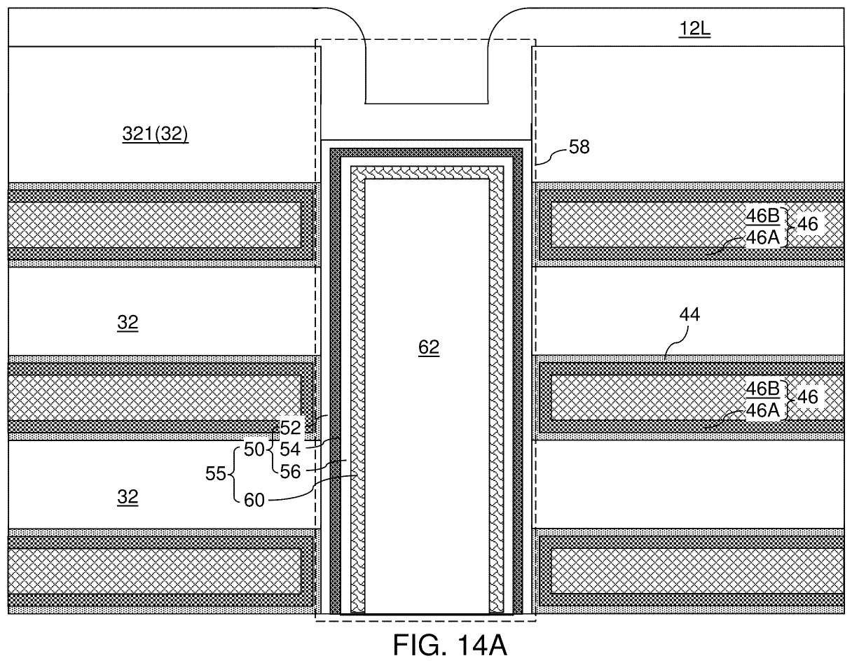

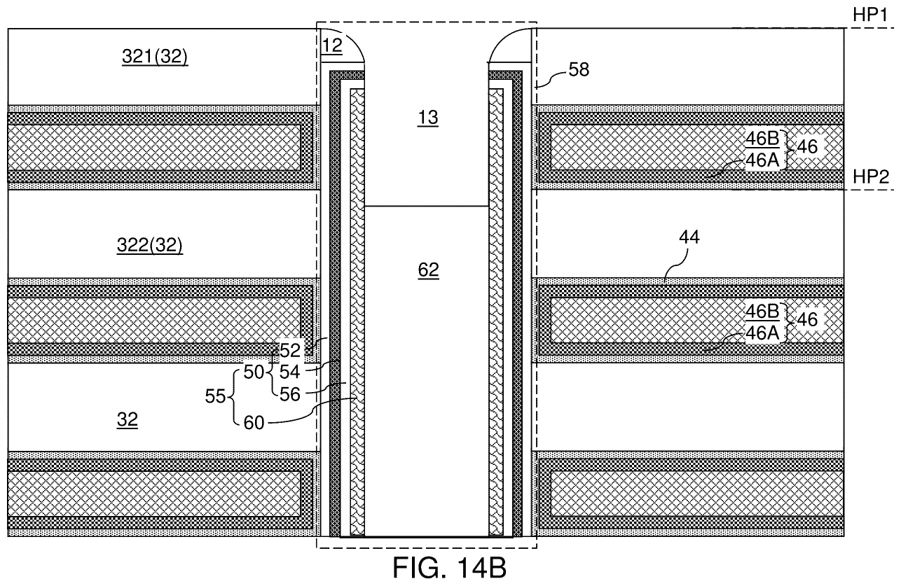

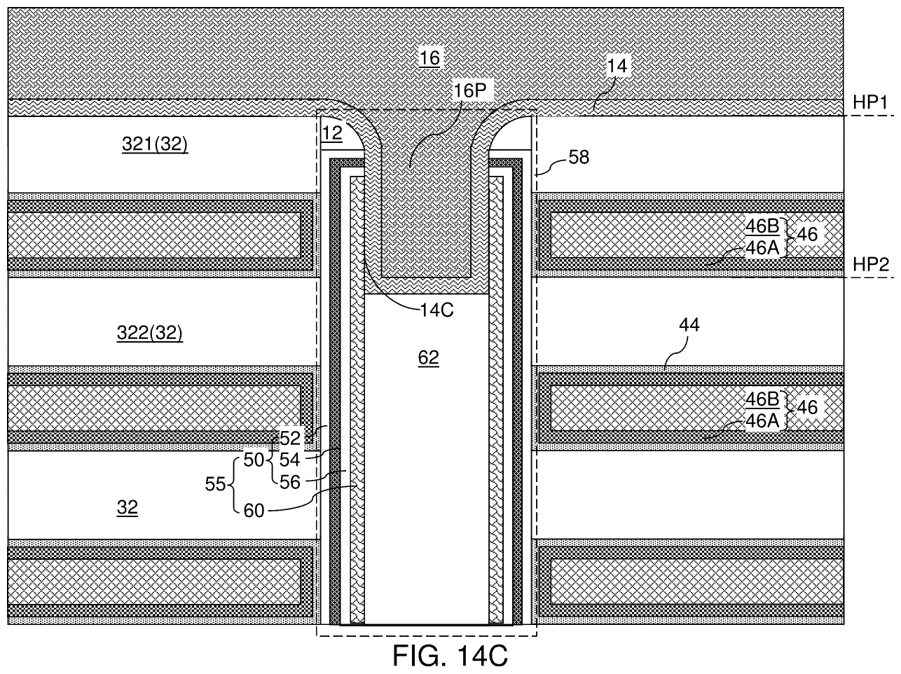

FIGS. 14A-14C are sequential vertical cross-sectional views of a region of the first exemplary structure during formation of an interfacial source layer 14 and a primary source layer 16 according to the first embodiment of the present disclosure.

Referring to FIG. 14A, an insulating material layer 12L, such as silicon oxide layer, can be deposited in peripheral portions of the cavities 13 and on the physically exposed backside surface of the mot proximal insulating layer 321 by a conformal deposition process. In one embodiment, the thickness of the insulating material layer 12L can be 20 nm to 50 nm. In one embodiment, the thickness of the insulating material layer 12L can be the same as or can be greater than the sum of the thickness of a memory film 50 and the thickness of a vertical semiconductor channel 60. In one embodiment, the difference between the thickness of the insulating material layer 12L and the sum of the thickness of a memory film 50 and the thickness of a vertical semiconductor channel 60 may be in a range from 0 nm to 20 nm, such as from 0 nm to 10 nm. The thickness of the insulating material layer 12L can be less than one half of the lateral dimension (such as a diameter) of each memory opening fill structure 58.

Referring to FIG. 14B, an anisotropic etch process (e.g., sidewall spacer etch process) can be performed to remove horizontally-extending portions of the insulating material layer 12L, and further remove horizontally-extending potions of the memory films 50, the vertical semiconductor channels 60, and proximal portions of the dielectric cores 62 that are not masked by vertically-extending portions of the insulating material layer 12L. In one embodiment, a horizontal surface of the most proximal insulating layer 321 can be physically exposed. The horizontal plane including the physically exposed horizontal surface of the most proximal insulating layer 321 is herein referred to as a first horizontal plane HP1. In one embodiment, the anisotropic etch process can be continued until a physically exposed surface of each dielectric core 62 is vertically recessed below a horizontal plane including a proximal horizontal surface of the second nearest insulating layer 322. The second nearest insulating layer 322 is the insulating layer 32 that is closest to the most proximal (i.e., bottom) insulating layer 321. The horizontal plane including the horizontal surface of the second nearest insulating layer 322 is herein referred to as a second horizontal plane HP2.

Each remaining portion of the insulating material layer 12L located at a periphery of a respective cavity 13 constitutes an annular insulating spacer 12. In one embodiment, each annular insulating spacer 12 can contact an annular end surface of the memory film 50, and can contact an inner sidewall of an opening through a most proximal insulating layer 321 of the insulating layers 32.

The anisotropic etch process may comprise an isotropic etch component that is sufficient to remove portions of a respective dielectric core 62 around each cavity 13. A surface of the vertical semiconductor channel 60 can be physically exposed from the side of the memory opening 49 from which the carrier substrate 9 is removed. In one embodiment, an end portion of an inner sidewall of each vertical semiconductor channel 60 is physically exposed to a respective cavity 13. In one embodiment, each memory opening fill structure 58 comprises a sacrificial pillar structure 11 on which a memory film 50 and a vertical semiconductor channel 60 are formed, and a cavity 13 can be formed by removing the sacrificial pillar structure and end portions of the memory film 50 and the vertical semiconductor channel 60 that are proximal to the sacrificial pillar structure 11.

Referring to FIG. 14C, an interfacial source layer 14 comprising a second semiconductor material can be conformally deposited on the physically exposed surfaces of the dielectric core 52, the vertical semiconductor channel 60, the memory film 50, and the annular insulating spacer 12 of each memory opening fill structure 58, and on the physically exposed backside surface of the most proximal insulating layer 321. According to an aspect of the present disclosure, the second semiconductor material is different from the first semiconductor material. In one embodiment, the first semiconductor material of the vertical semiconductor channels 60 may include a first semiconductor material having a first band gap, and the second semiconductor material of the interfacial source layer 14 may include a second semiconductor material having a second band gap that is smaller than the first band gap. For example, the first semiconductor material of the vertical semiconductor channels 60 may comprise silicon (e.g., polysilicon), and the second semiconductor material of the interfacial source layer 14 may comprise silicon germanium containing between 10 and 70 atomic percent germanium and between 30 and 90 atomic percent silicon. The second semiconductor material of the interfacial source layer 14 may be intrinsic (i.e., not intentionally doped) or it may have a conductivity of a second type which is opposite of the first conductivity type. For example, the second semiconductor material of the interfacial source layer 16 may comprise intrinsic silicon germanium or n-type silicon germanium doped with phosphorus and/or antimony.

The interfacial source layer 14 is deposited directly on an end portion of the inner sidewall of the vertical semiconductor channel 60 at least in a first portion of each cavity 13. In one embodiment, the interfacial source layer 14 is in contact with a cylindrical surface segment of an inner sidewall of the vertical semiconductor channel 60. The thickness of the interfacial source layer 14 may be in a range from 3 nm to 60 nm, such as from 6 nm to 30 nm, although lesser and greater thicknesses may also be employed.

Subsequently, a primary source layer 16 comprising a third semiconductor material can be deposited over the interfacial source layer 14 in the remaining second portion of each cavity 13 and over a horizontally-extending surface of the most proximal insulating layer 321. The third semiconductor material is different from the second semiconductor material, and has a third band gap that is different from the second band gap. In one embodiment, the third band gap can be greater than the second band gap. In one embodiment, the first band gap can be the same as the third band gap. For example, the third semiconductor material of primary source layer 16 may comprise silicon (e.g., polysilicon) having a conductivity of a second type which is opposite of the first conductivity type. For example, the third semiconductor material of primary source layer 16 may comprise n-type polysilicon doped with phosphorus and/or antimony. In one embodiment, the interfacial source layer 14 contacts an end portion of an inner cylindrical sidewall of each memory film 50 and the vertical semiconductor channel 60, and the primary source layer 16 is not in direct contact with the memory films 50 and the vertical semiconductor channel 60.

The primary source layer 16 comprises vertically-protruding portions 16P that are located in an end portion of a respective one of the memory opening 49 and vertically extends at least between the first horizontal plane HP1 and the second horizontal plane HP2. The first horizontal plane HP1 now includes a horizontal interface between the most proximal insulating layer 321 of the insulating layers 32 and the interfacial source layer 14. The second horizontal plane HP2 includes a proximal horizontal surface of the second nearest insulating layer 322 of the insulating layers 32.

In one embodiment, an interface between a vertical semiconductor channel 60 and the interfacial source layer 14 comprises a cylindrical area 14C that is more proximal the horizontal plane HP1 than the dielectric core 62 is to the first horizontal plane HP1. In one embodiment, each memory opening fill structure 58 comprises a dielectric core 62 that is laterally surrounded by a vertical semiconductor channel 60, and a drain region 63 in contact with an end portion of the vertical semiconductor channel 60 and is vertically spaced from the source layers (14, 16) by the dielectric core 62.

In one embodiment, the first semiconductor material of each vertical semiconductor channel 60 comprises and/or consists essentially of a first doped silicon material having a doping of a first conductivity type, the second semiconductor material of the interfacial source layer 14 comprises and/or consists essentially of an intrinsic or doped silicon-germanium alloy material having a doping of a second conductivity type that is an opposite of the first conductivity type; and the third semiconductor material of the primary source layer 16 comprises and/or consists essentially of a second doped silicon material having a doping of the second conductivity type. In one embodiment, the atomic concentration of dopants of the second conductivity type in the interfacial source layer 14 may be in a range from 1.0×10¹⁴/cm ³to 5.0×10¹⁹/cm³, and the atomic concentration of dopants of the second conductivity type in the primary source layer 16 may be in a range from 5.0×10¹⁸/cm³ to 2.0×10²¹/cm³. In one embodiment, the atomic concentration of the dopants of the second conductivity type is higher in the primary source layer 16 than in the interfacial source layer 14.

Referring to FIG. 15, a photoresist layer (not shown) can be applied over the primary source layer 16, and can be lithographically patterned into a desired shape. An anisotropic etch process can be performed to transfer the pattern in the photoresist layer through the primary source layer 16 and the interfacial source layer 14. Each contiguous combination of an interfacial source layer 14 and a primary source layer 16 constitutes a source structure (14, 16).

At least one backside dielectric layer 17 can be subsequently deposited over the source structure (14, 16). Optionally, backside metal interconnect structures (not shown) may be formed within the at least one backside dielectric layer 17. If present, the backside metal interconnect structures may comprise backside metal line structures and backside metal via structures. Backside bonding pads (18S, 18C) can be formed on the backside of the at least one backside dielectric layer 17. The backside bonding pads (18S, 18C) may comprise source-side backside bonding pads 18S that are electrically connected to the source structures (14, 16), and connection backside bonding pads 18C that are electrically connected to the through-memory-level via structures 82. The source-side backside bonding pads 18S may directly contact the backside of a respective one of the source structures (14, 16), or may be electrically connected to the respective one of the source structures (14, 16) through a respective subset of the backside metal interconnect structures. Further, the connection backside bonding pads 18C may directly contact a respective one of the through-memory-level via structures 82, or may be electrically connected to the respective one of the through-memory-level via structures 82 through a respective subset of the backside metal interconnect structures.

In one embodiment, the primary source layer 16 comprises a horizontally-extending portion that underlies a most proximal insulating layer 321 of the insulating layers 32 of the alternating stack (32, 46). In one embodiment, the horizontally-extending portion of the primary source layer 16 is vertically spaced from the most proximal insulating layer 321 by a horizontally-extending portion of the interfacial source layer 14 that contacts a horizontal surface of the most proximal insulating layer 321.

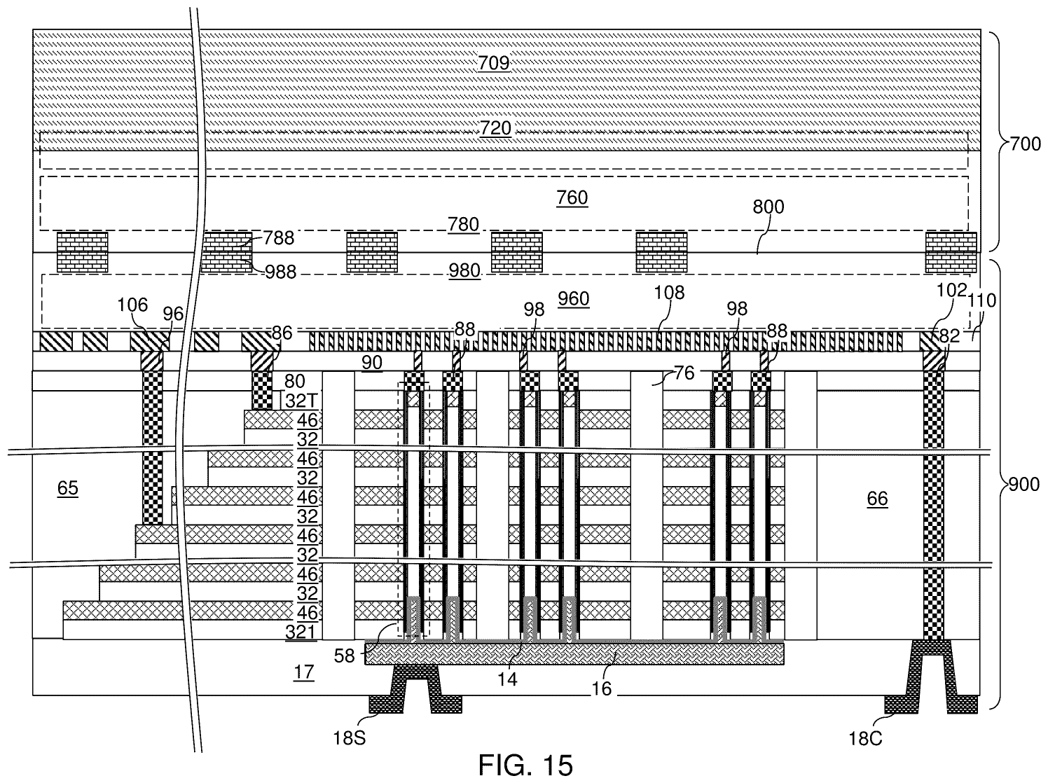

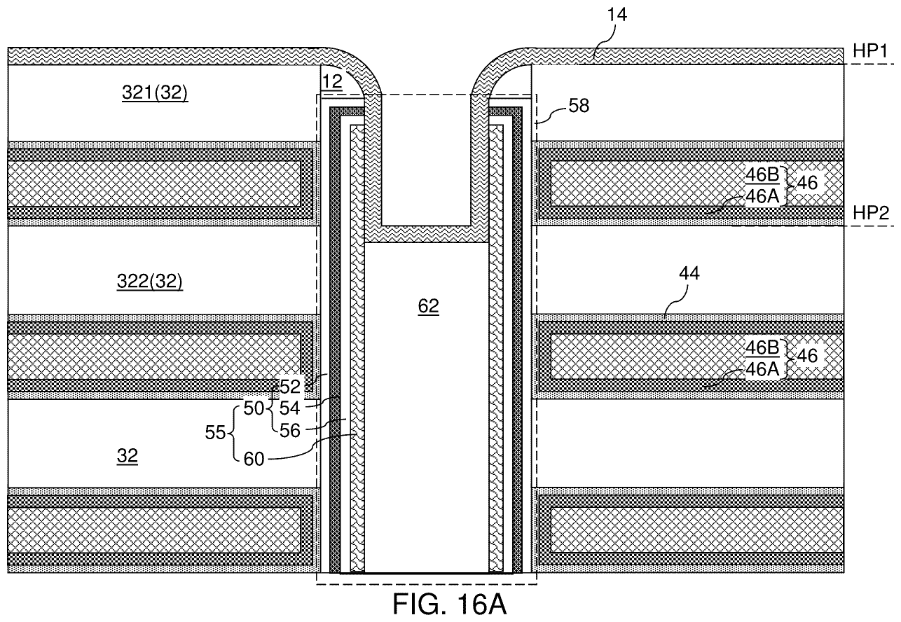

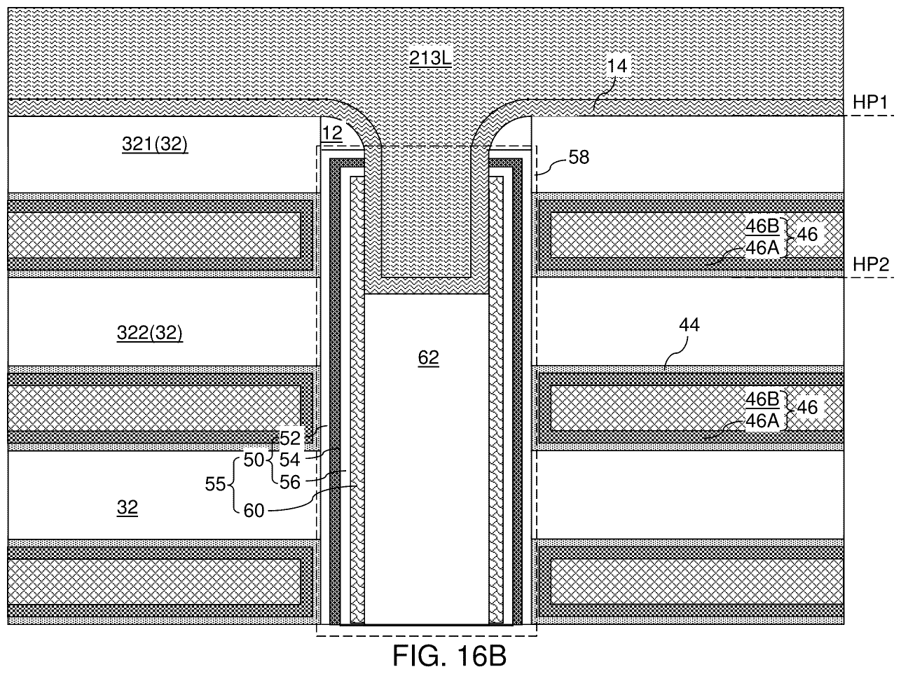

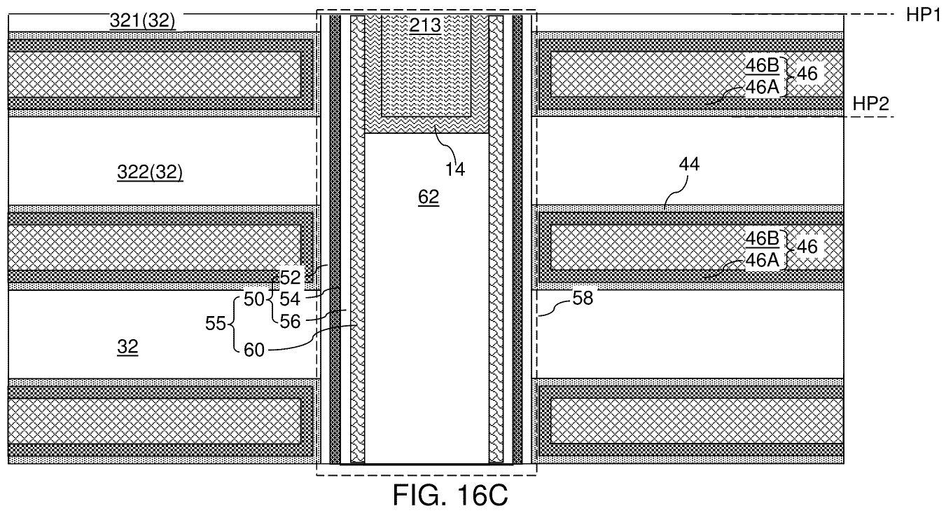

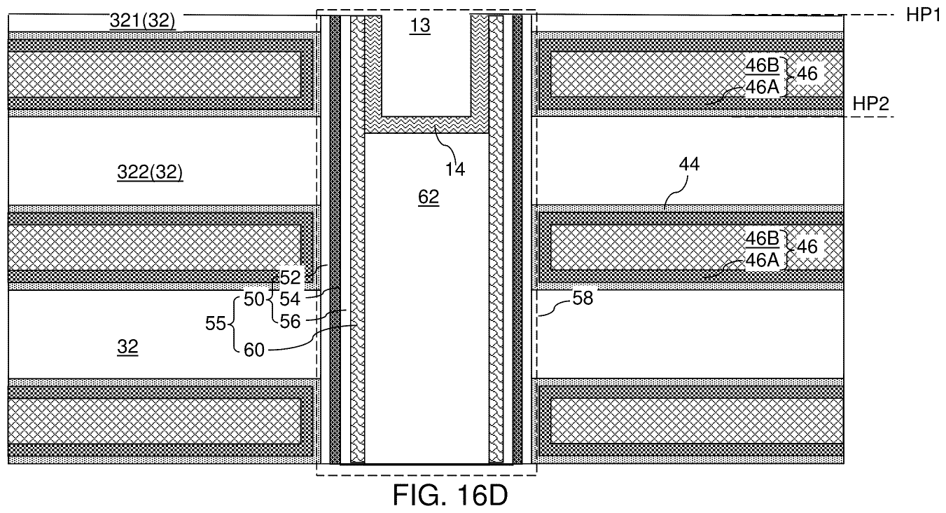

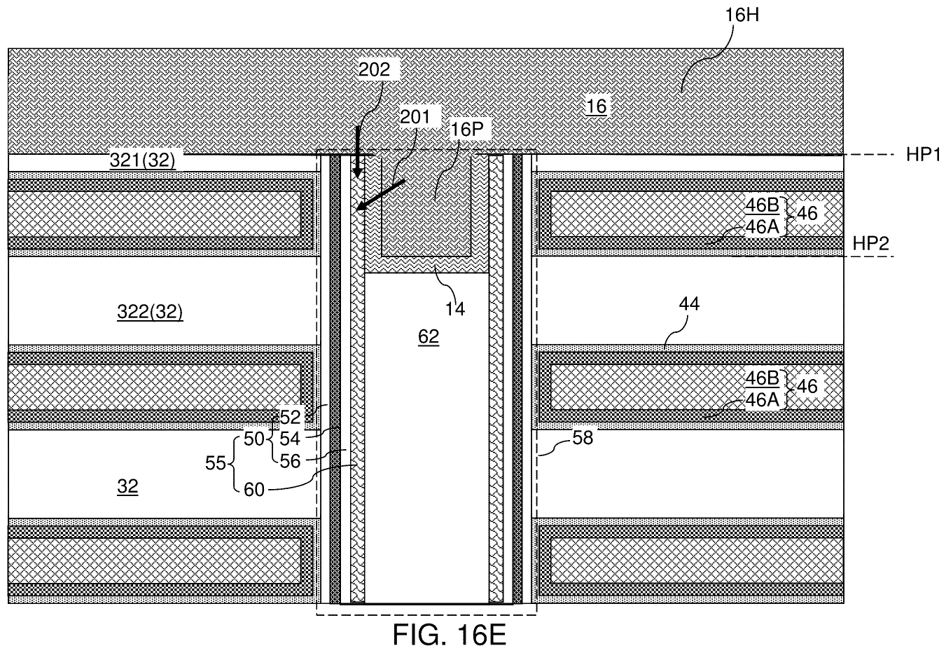

Referring to FIGS. 16A-16E, sequential vertical cross-sectional views of a region of a second exemplary structure are illustrated during formation of an interfacial source layer 14 and a primary source layer 16 according to a second embodiment of the present disclosure. Generally, the second exemplary structure can be the same as the first exemplary structure up to the processing steps described with reference to FIG. 14B.

Referring to FIG. 16A, the second exemplary structure can be derived from the first exemplary structure illustrated in FIG. 14B by performing a processing step described with reference to FIG. 14C. Specifically, the interfacial source layer 14 comprising a second semiconductor material can be conformally deposited on the physically exposed surfaces of the dielectric core 62, the vertical semiconductor channel 60, the memory film 50, and the annular insulating spacer 12 of each memory opening fill structure 58, and on the physically exposed backside surface of the most proximal insulating layer 321. The interfacial source layer 14 in the second exemplary structure may have the same material composition and the same thickness as in the first exemplary structure. The interfacial source layer 14 is formed directly on the end portion of the inner sidewall of each memory film 50. In one embodiment, the interfacial source layer 14 contacts an end portion of a respective inner cylindrical sidewall of each memory film 50 and an inner sidewall of the vertical semiconductor channel 60.

Referring to FIG. 16B, a sacrificial fill material layer 213L can be deposited in the remaining volumes of the cavities 13 and over the interfacial source layer 14. In one embodiment, the sacrificial fill material layer 213L may comprise a carbon material, such as spin-on carbon (SoC), amorphous carbon, diamond-like carbon (DLC), or a polymer material. In another embodiment, the sacrificial material layer 213L comprises a doped semiconductor material of the second conductivity type which has the same composition as the primary source layer 16. For example the sacrificial material layer 213L may comprise n-type polysilicon.

Referring to FIG. 16C, a planarization process, such as a chemical mechanical polishing (CMP) process, can be performed to remove portions of the interfacial source layer 14 and the sacrificial fill material layer 213 that overlies the first horizontal plane HP1. The first horizontal plane is the horizontal plane that includes the horizontal surface of the most proximal insulating layer 321 that is distal from the bonding interface 800 between the memory die 900 and the logic die 700 and is physically exposed after the planarization process. The interfacial source layer 14 is divided into a plurality of interfacial source layers 14 located within a respective one of the cavities 13. Each remaining portion of the sacrificial fill material layer 213L located within a respective one of the cavities 13 constitutes a sacrificial fill material portion 213. Each cavity 13 can be filled with a combination of a respective interfacial source layer 14 and a respective sacrificial fill material portion 213. Physically exposed surfaces of the interfacial source layers 14, the vertical semiconductor channels 69 and the sacrificial fill material potions 213 may be located within the first horizontal plane HP1.

Referring to FIG. 16D, the sacrificial fill material potions 213 can optionally be removed selective to the interfacial source layers 14 and the most proximal insulating layer 321. For example, if the sacrificial fill material potions 213 comprise a carbon-based material, an ashing process may be performed to remove the sacrificial fill material portions 213. Alternatively, if the sacrificial fill material potions 213 comprise the doped semiconductor material of the second conductivity type which has the same composition as the primary source layer 16, then the removal step shown in FIG. 16D is omitted and the sacrificial fill material potions 213 are retained in the cavities 13.

Referring to FIG. 16E, the processing steps described with reference to FIG. 14C can be performed to form a primary source layer 16. The primary source layer 16 in the second exemplary structure may have the same material composition and the same thickness range as in the first exemplary structure. The primary source layer 16 is continuous and contacts the horizontal surface of the most proximal insulating layer 321 that is distal from the bonding interface 800 and the plural interfacial source layers 14. The primary source layer 16 includes the vertically-protruding portions 16P contacting the plural interfacial source layers 14 and a horizontally-extending portion 16H contacting the end portions (i.e., horizontal end tips) of the vertical semiconductor channels 60 and the memory films 50, and contacting the horizontal surface of the most proximal insulating layer 321. In one embodiment, both the vertically-protruding portions 16P and the horizontally-extending portion 16H can be deposited in the deposition step shown in FIG. 16E if the sacrificial fill material potion 213 is removed in the step shown in FIG. 16D. Alternatively, only the horizontally-extending portion 16H can be deposited in the deposition step shown in FIG. 16E if the doped semiconductor sacrificial fill material potion 213 is retained in the cavity 13. In this case, the doped semiconductor sacrificial fill material potion 213 forms the vertically-protruding portion 16P of the primary source layer 16.

The second exemplary structure includes two different current paths between the primary source layer 16 and the vertical semiconductor channel 60. The first current path 201 comprises an indirect, non-vertical current path through the interfacial source layer 14, between the vertically-protruding portion 16P of the primary source layer 16 and an inner vertical sidewall of the vertical semiconductor channel 60, similar to the current path of the first exemplary structure. The second current path 202 comprises a direct vertical current path between the horizontal tip of the vertical semiconductor channel 60 and the horizontally-extending portion 16H of the primary source layer 16.

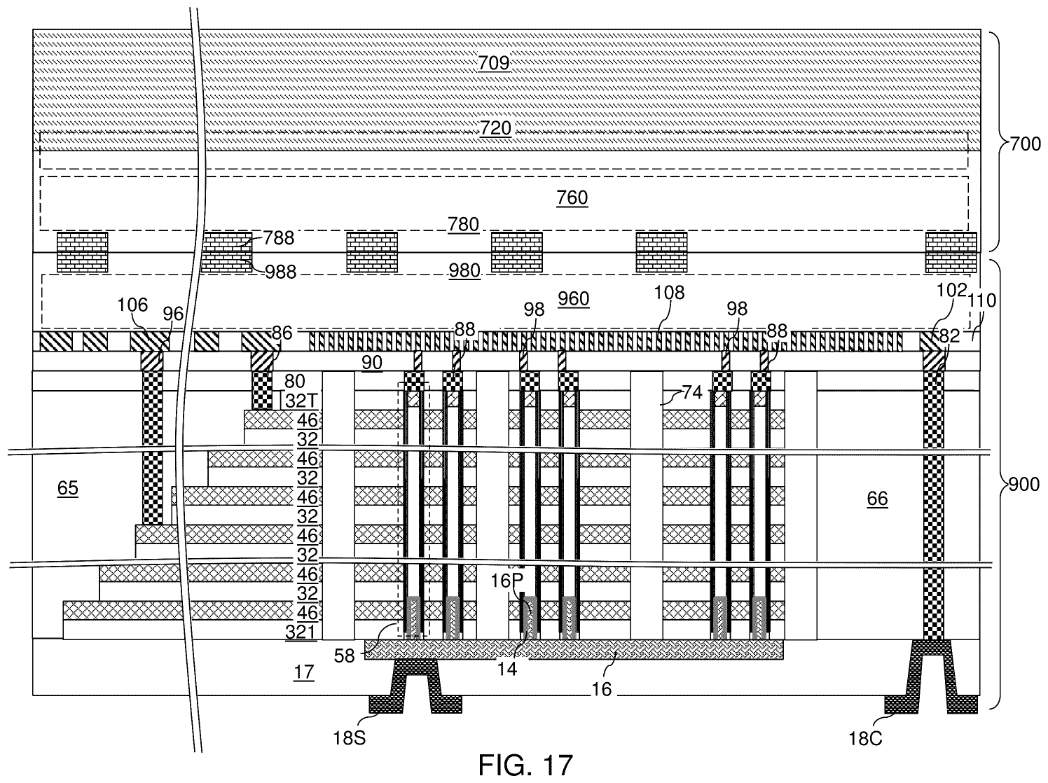

Referring to FIG. 17, the processing steps described with reference to FIG. 15 can be performed to pattern the primary source layer 16. Source structures (14, 16) can be formed, each of which includes a respective interfacial source layer 14 located entirely within a respective cavity 13 and a primary source layer 16 including a vertically-protruding portion 16P and a horizontally-extending portion 16H. At least one backside dielectric layer 17 and backside bonding pads (18S, 18C) can be formed as described with reference to FIG. 15. The horizontally-extending portion of the primary source layer 16 in each source structure (14, 16) can be in direct contact with an end portion of the vertical semiconductor channel 60 and a horizontal surface of the most proximal insulating layer 321.

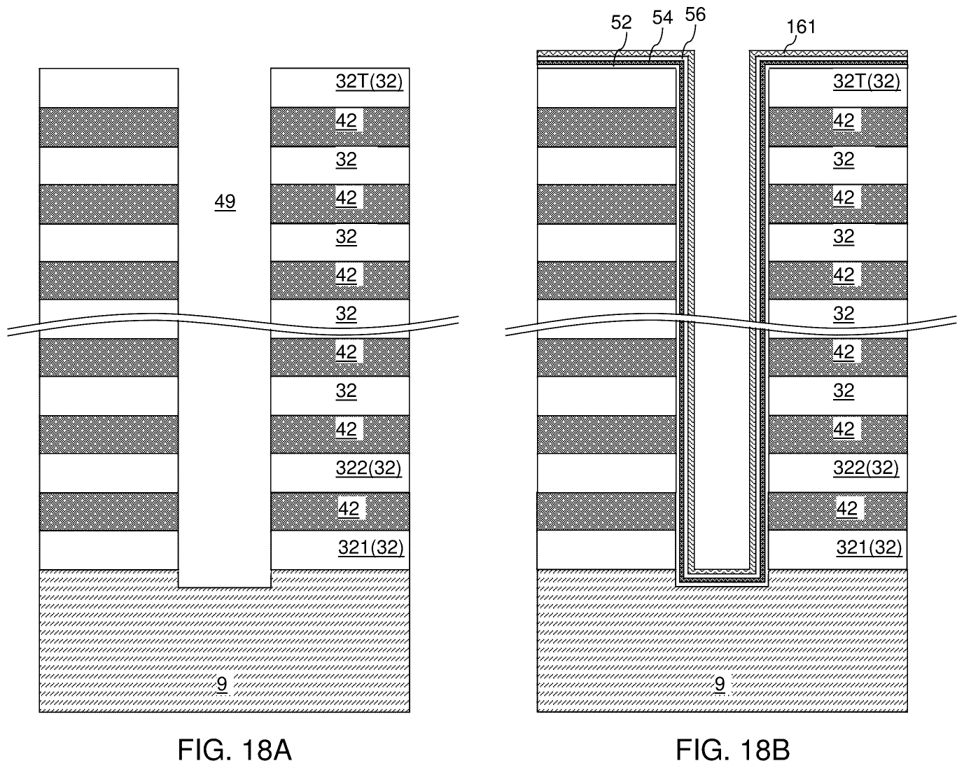

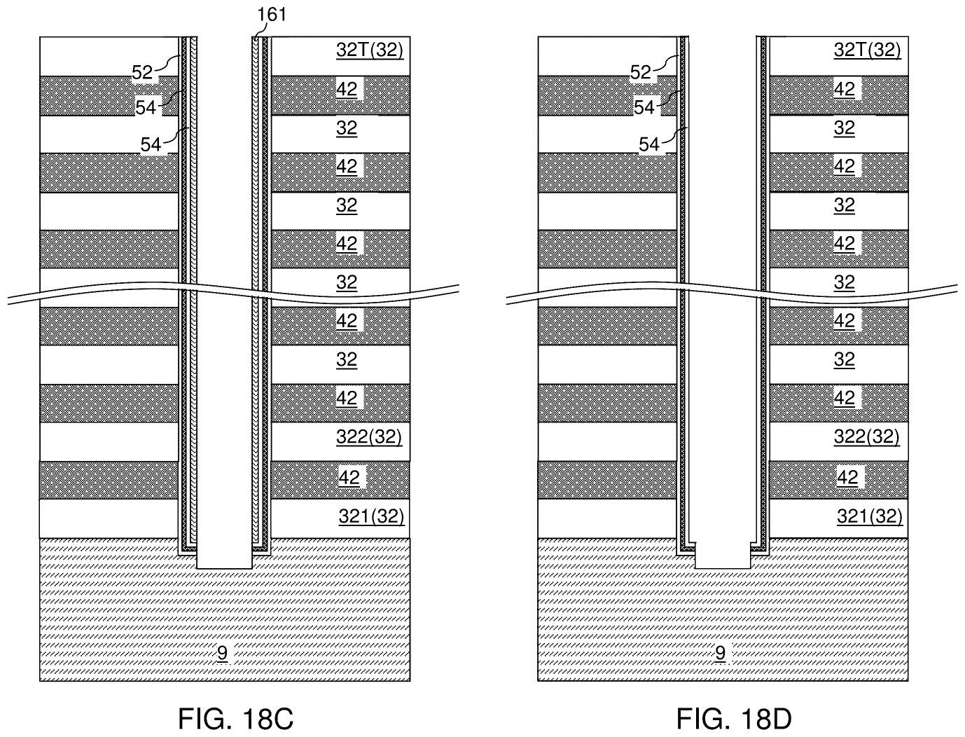

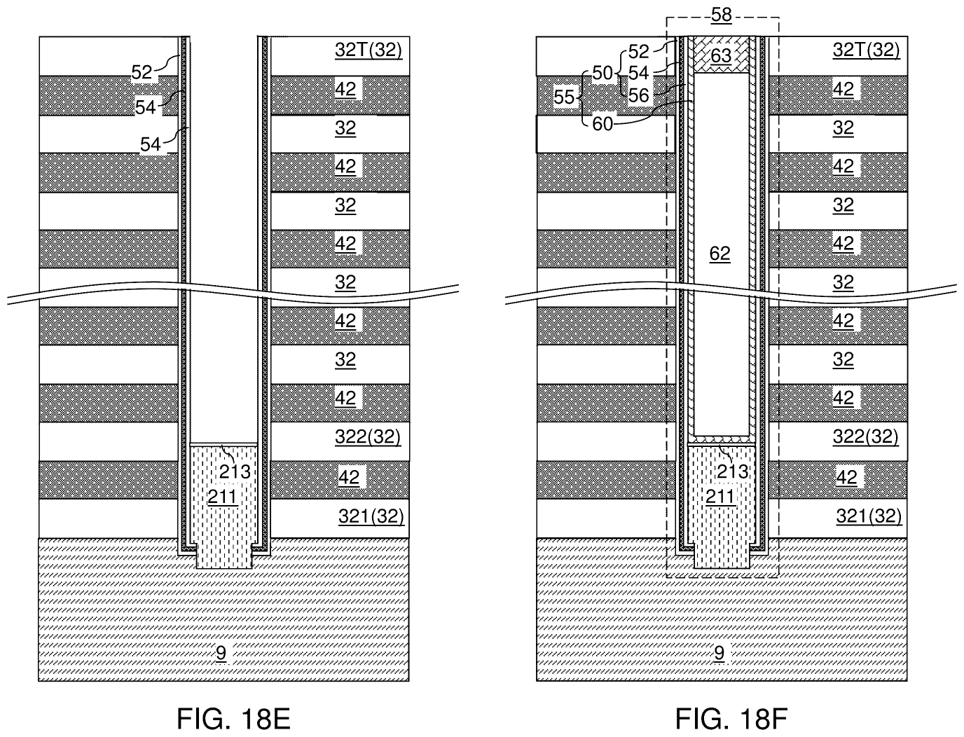

Referring to FIGS. 18A-18E, a memory opening 49 in a third exemplary structure is illustrated during formation of a memory opening fill structure 58 in a memory opening 49.

Referring to FIG. 18A, the third exemplary structure may be the same as the first exemplary structure illustrated in FIGS. 3A, 3B, and 4A. The formation of the sacrificial pillar structures 11 of FIG. 4B may be omitted in the third embodiment.

Referring to FIG. 18B, the processing steps described with reference to FIG. 4B may be performed to form an optional blocking dielectric layer 52, a memory material layer 54, an optional dielectric liner 56, and an optional sacrificial cover layer 161. Each of the optional blocking dielectric layer 52, the memory material layer 54, and the optional dielectric liner 56 may have the same material composition as in the first exemplary structure. The optional sacrificial cover layer 161 comprises a sacrificial cover material that can protect vertically-extending portions of the optional dielectric liner 56 and/or the memory material layer 54 during a subsequent anisotropic etch process. For example, the optional sacrificial cover layer 161 may comprise a semiconductor material (such as amorphous silicon) or a carbon-based material (such as amorphous carbon).

Referring to FIG. 18C, an anisotropic etch process can be performed to remove horizontally-extending portions of the optional sacrificial cover layer 161, the optional dielectric liner 56, the memory material layer 54, and the optional blocking dielectric layer 52. A top surface of the carrier substrate 9 can be physically exposed at the bottom of each memory opening 49. Referring to FIG. 18D, the optional sacrificial cover layer 161, if present, can be removed selective to the material of the optional dielectric liner 56 or the memory material layer 54 (in case the optional dielectric liner 56) is not employed.

Referring to FIG. 18E, a selective semiconductor growth process can be performed to grow a semiconductor material from the physically exposed surface of the carrier substrate 9 while suppressing growth of the semiconductor material from the physically exposed surfaces of the optional dielectric liner 56, the memory material layer 54, the optional blocking dielectric layer 52, and the topmost insulating layer 32T. In an illustrative example, the carrier substrate 9 may comprise a single crystalline silicon substrate, and the selective semiconductor growth process may grow a single crystalline silicon material from the physically exposed surfaces of the carrier substrate 9 to form a sacrificial pillar structure 211 at the bottom of each memory opening 49. In one embodiment, a semiconductor precursor gas (such as silane, disilane, dichlorosilane, digermane, etc.) and an etchant gas (such as gaseous hydrogen chloride) can be concurrently or alternately flowed into a process chamber in which the third exemplary structure is placed during the selective semiconductor growth process.

In one embodiment, the duration of the selective semiconductor growth process can be selected such that each of the sacrificial pillar structures 211 comprises a respective top surface that is formed between the bottommost insulating layer (i.e., the most proximal insulating layer 321) and the insulating layer that is most proximal to the bottommost insulating layer (i.e., the second nearest insulating layer 322). An oxidation process may be performed to convert physically exposed surface portions of the sacrificial pillar structures 211 into dielectric semiconductor oxide plates 213. If the sacrificial pillar structures 211 comprise single crystalline silicon or polysilicon, then the dielectric semiconductor oxide plates 213 may comprise silicon oxide. The thickness of the sacrificial pillar structures 211 may be in a range from 3 nm to 10 nm, although lesser and greater thicknesses may also be employed.

Referring to FIG. 18F, a semiconductor channel material layer and a dielectric core layer can be deposited in each remaining volume of the memory openings 49 and over the topmost insulating layer 32T. A recess etch process can be performed to form a dielectric core 62 within each memory opening 49. The processing steps described with reference to FIG. 4D can be performed to form a drain region 63 and a vertical semiconductor channel 60 within each memory opening 49. Generally, the vertical semiconductor channels 60 in the third exemplary structure may have the same material composition and the same thickness range as in the first exemplary structure. Thus, the vertical semiconductor channels 60 in the third exemplary structure may comprise a first semiconductor material having a doping of the first conductivity type in the same manner as in the first exemplary structure.

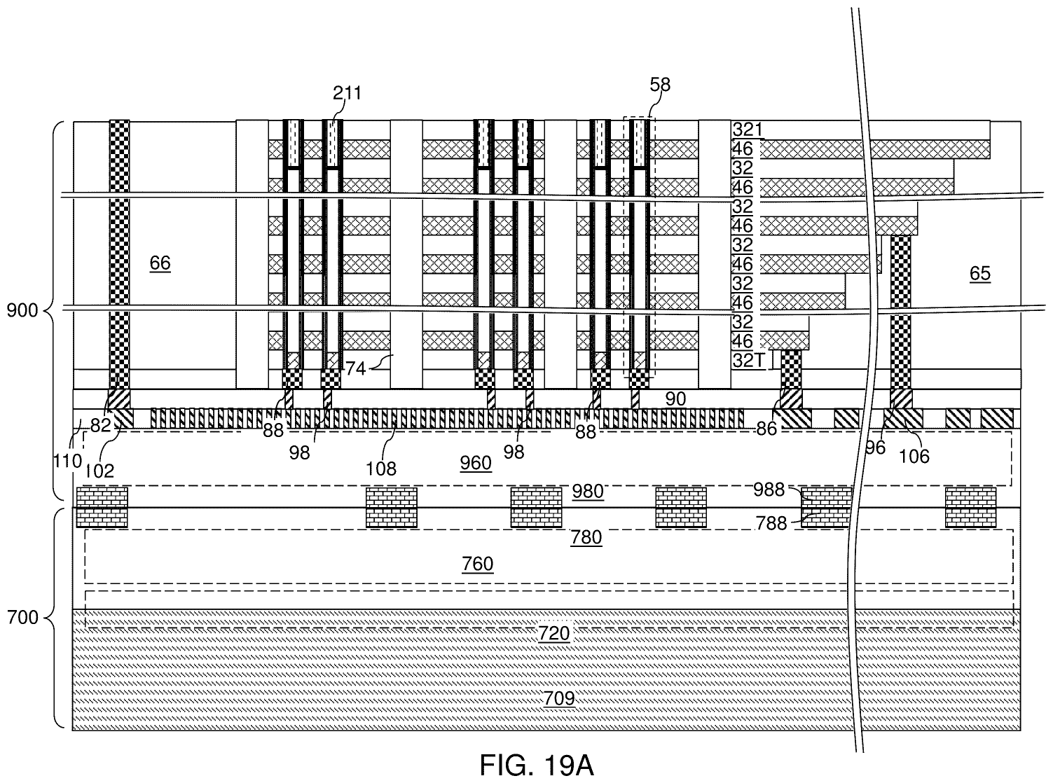

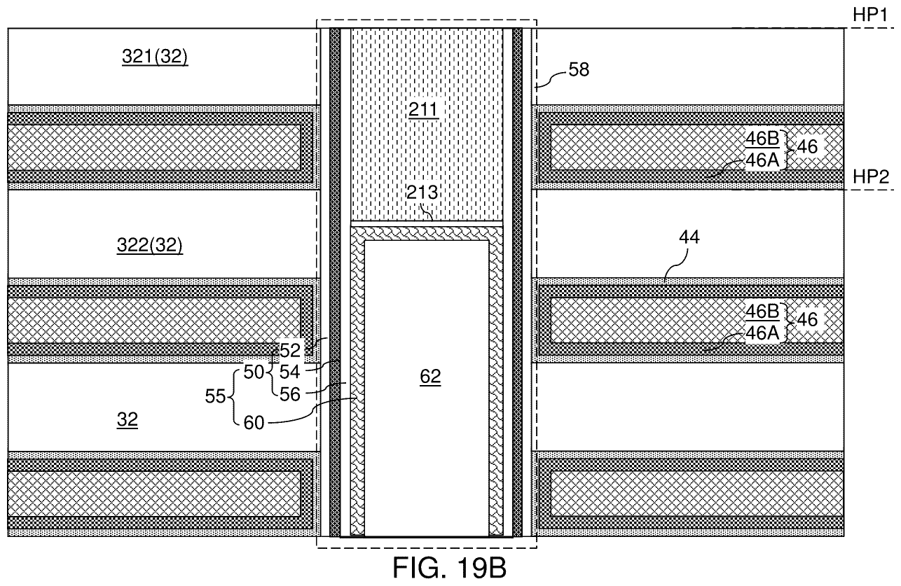

Referring to FIGS. 19A and 19B, the processing steps described with reference to FIGS. 6A-13B can be performed to provide the third exemplary structure illustrated in FIGS. 19A and 19B. The carrier substrate 9 can be removed, and end surfaces of the sacrificial pillar structures 211 can be physically exposed. Alternatively, the sacrificial pillar structures 211 may be removed selective to the memory films 50 during removal of the carrier substrate 9.

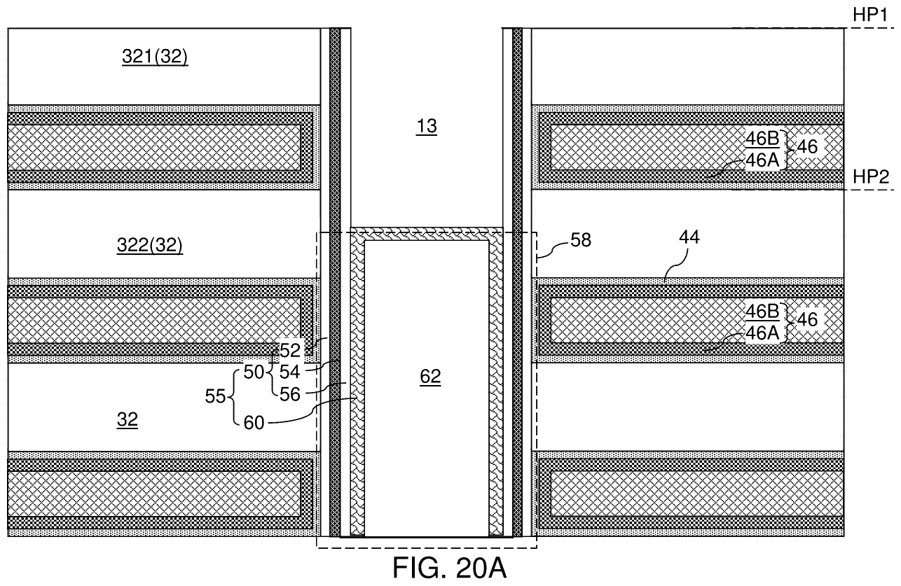

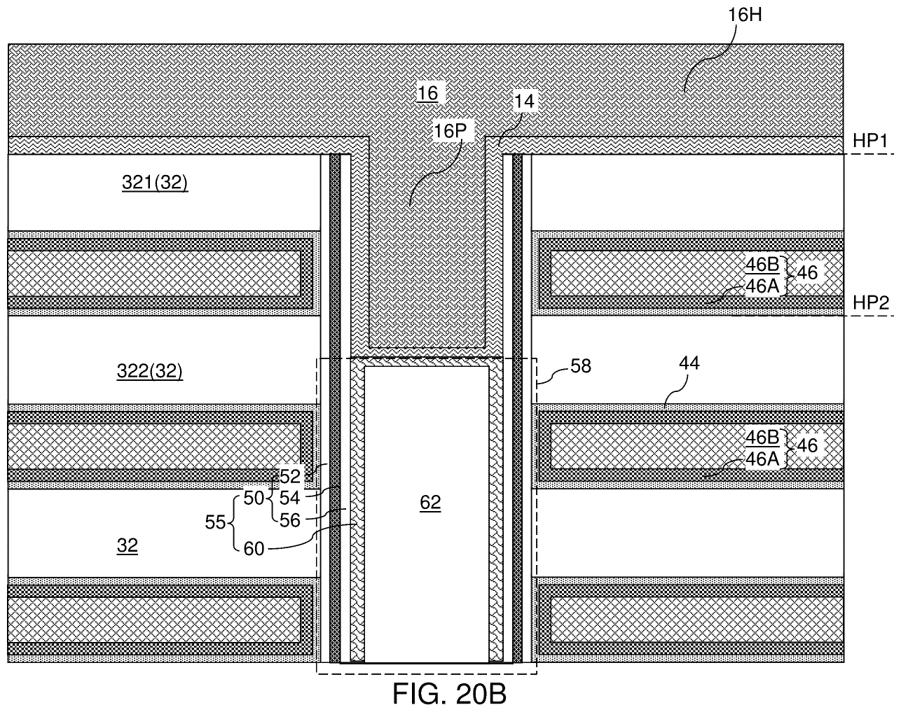

FIGS. 20A and 20B are sequential vertical cross-sectional views of a region of the third exemplary structure during formation of an interfacial source layer 14 and a primary source layer 16 according to the third embodiment of the present disclosure.

Referring to FIG. 20A, in case the sacrificial pillar structures 211 remain after removal of the carrier substrate 9 from the bonded assembly of the memory die 900 and the logic die 700, a selective etch process can be performed to remove the sacrificial semiconductor material of the sacrificial pillar structures 211 selective to the materials of the memory film 50, the dielectric semiconductor oxide plates 213, and the most proximal insulating layer 321. In an illustrative example, a wet etch process using hot trimethyl-2 hydroxyethyl ammonium hydroxide (“hot TMY”) or tetramethyl ammonium hydroxide (TMAH) may be used to remove the silicon sacrificial pillar structures 211 selective to the memory film 50, the dielectric semiconductor oxide plates 213, and the most proximal insulating layer 321.

Subsequently, the dielectric semiconductor oxide plates 213 can be removed by performing an etch process, which may comprise an anisotropic etch process (such as a reactive ion etch process) or an isotropic etch process (such as a wet etch process). A horizontally-extending end portion of the vertical semiconductor channels 60 is exposed in the cavity 13.

Referring to FIG. 20B, the processing steps described with reference to FIG. 14C can be performed to form an interfacial source layer 14 and a primary source layer 16. The interfacial source layer 14 may contact an end portion of an inner cylindrical sidewall of each memory film 50. Further, the interfacial source layer 14 may be in contact with a horizontal end surface of each vertical semiconductor channel 60. The primary source layer 16 vertically extends at least between the first horizontal plane HP1 and the second horizontal plane HP2 (which includes the proximal horizontal surface of the second nearest insulating layer 322). The primary source layer 16 is not in direct contact with the memory films 50.

Referring to FIG. 21, the processing steps described with reference to FIG. 15 can be performed to pattern the interfacial source layer 14 and the primary source layer 16 to form the source structures (14, 16). At least one backside dielectric layer 17 and backside bonding pads (18S, 18C) can be formed as described with reference to FIG. 15. The horizontally-extending portion 16H of the primary source layer 16 in each source structure (14, 16) is vertically spaced from a horizontal surface of the most proximal insulating layer 321 by a horizontally-extending portion of a respective interfacial source layer 14.

FIG. 21 is a vertical cross-sectional view of the third exemplary structure after patterning the interfacial source layer 14 and the primary source layer 16 and formation of at least one backside dielectric layer and backside bonding pads according to the third embodiment of the present disclosure.

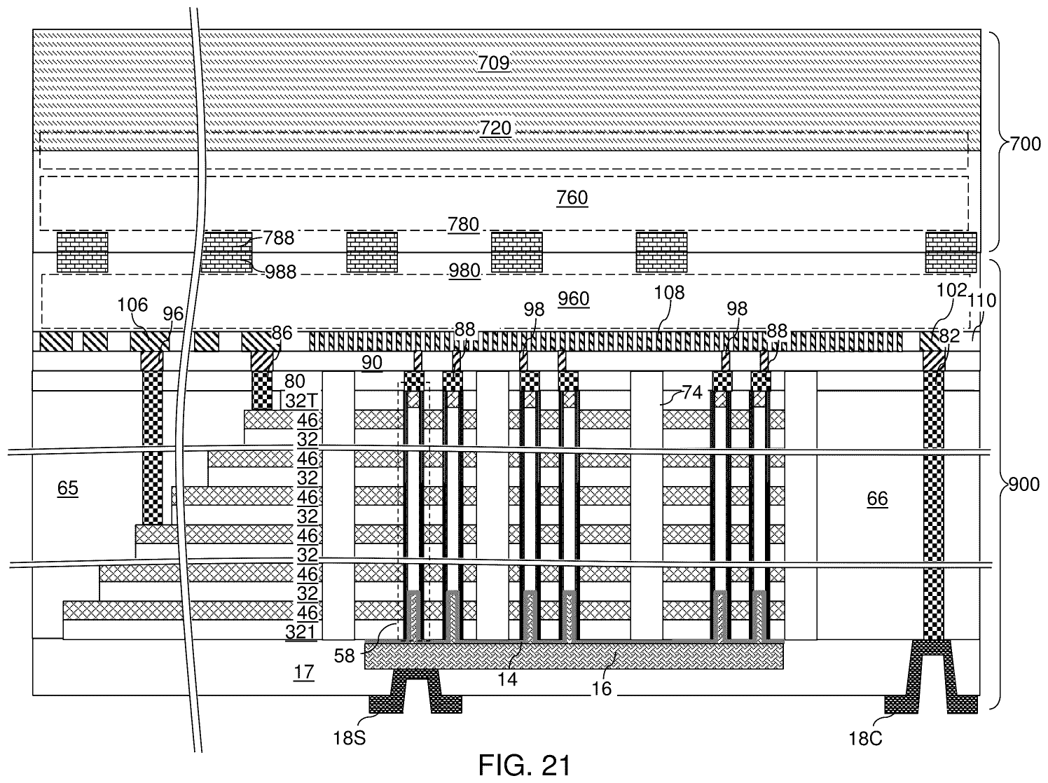

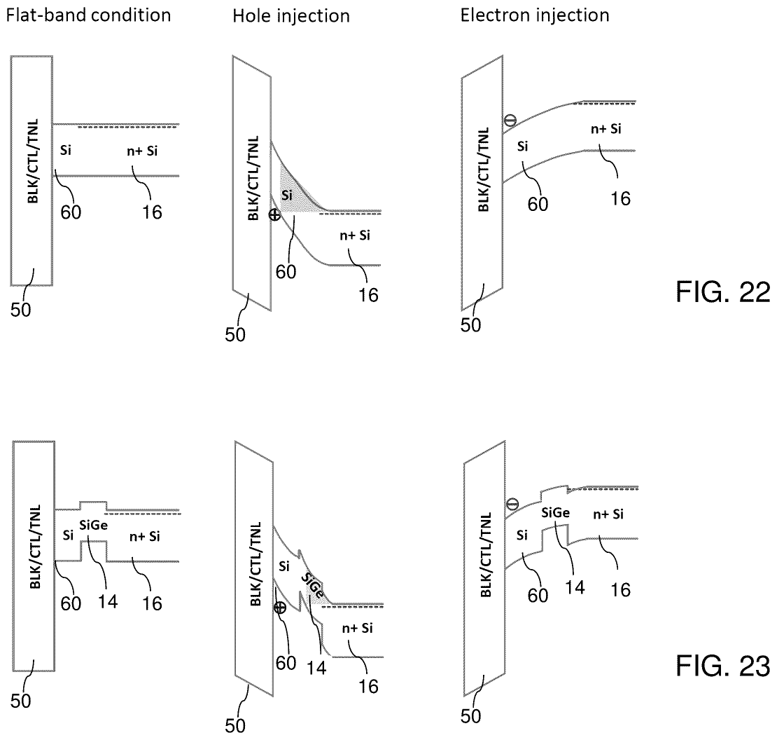

FIG. 22 illustrates band diagrams of a comparative exemplary structure in which only silicon is employed within a source structure during various operational modes during a flat band condition, hole injection and electron injection. A vertical semiconductor channel 60 consists of lightly p-doped silicon (represented by “Si”), and the source structure 16 consists of heavily n-doped silicon (represented by “n+Si”). The memory film 50 is represented by “BLK/CTL/TNL.”

FIG. 23 illustrates band diagrams of an exemplary structure according to the first embodiment of the present disclosure during a flat band condition, hole injection and electron injection. The band structures illustrated in FIG. 23 can be formed in the first embodiment that includes the source structure (14, 16). A vertical semiconductor channel 60 consists of lightly p-doped silicon (represented by “Si”), and the source structure (14, 16) comprises a layer stack including an interfacial source layer 14 composed of silicon germanium alloy (represented by “SiGe”) and a primary source layer 16 composed of heavily n-doped silicon (represented by “n+Si”). The memory film 50 is represented by “BLK/CTL/TNL.” The band diagrams illustrate reduction of an energy barrier during hole injection compared to the energy barrier of the comparative structure of FIG. 22. The reduction of the energy barrier during hole injection which may be advantageously employed during an gate induced source leakage (“GISL”) erase operation in which holes are injected from the source structure (14, 16) into the vertical semiconductor channel 60. The holes recombine with electrons stored in the charge storage layer 54 to erase the memory strings. The GISL erase is similar to the gate induced drain leakage (GIDL) erase, except that it is performed from the source side rather than from the drain side. Thus, the interfacial source layer 14 reduces the band to band tunneling barrier to improve the erase current. Furthermore, the vertical cylindrical area 14C interface between the vertical semiconductor channel 60 and the interfacial source layer 14 increases the electric field and hole tunneling area during the erase operation.

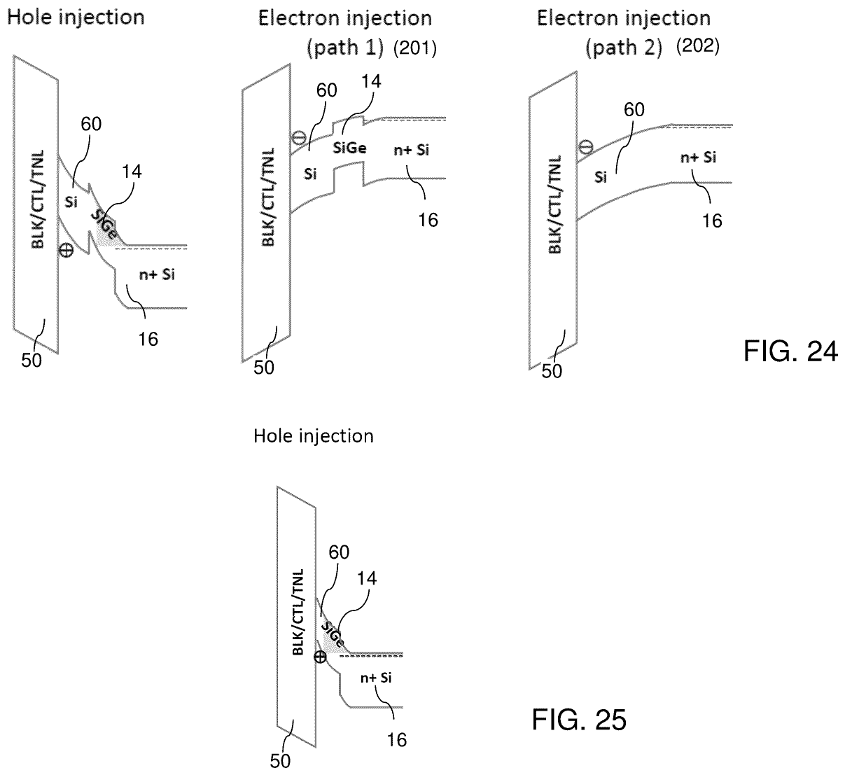

FIG. 24 illustrates band diagrams of the second exemplary structure according to the second embodiment of the present disclosure during hole injection and electron injection. As discussed above with respect to FIG. 16E, the second exemplary structure includes two different current paths 201 and 202. The band diagram for the first electron injection path (i.e., first current path 201) is shown in the middle band diagram. The band diagram for the second electron injection path (i.e., second current path 202) is shown in the right band diagram. Due to the addition of the direct second current path 202, the electrons from the primary source layer 16 do not have to pass through the SiGe barrier (interfacial source layer 14) to reach the vertical semiconductor channel 60. Therefore, the electron injection in the second embodiment is improved due to the addition of the direct second current path 202.

FIG. 25 illustrates a band diagram of the third exemplary structure according to the third embodiment of the present disclosure during hole injection. The contact between the horizontal portion of the vertical semiconductor channel 60 and the source structure (14, 16) provides a larger interface area, which improves the hole injection efficiency. Furthermore, since the vertical semiconductor channel 60 is not present adjacent to the bottommost source side select gate electrode which may be used to apply the GISL voltage, enhances the gate control and band bending steepness, thus leading to an improved GISL erase.

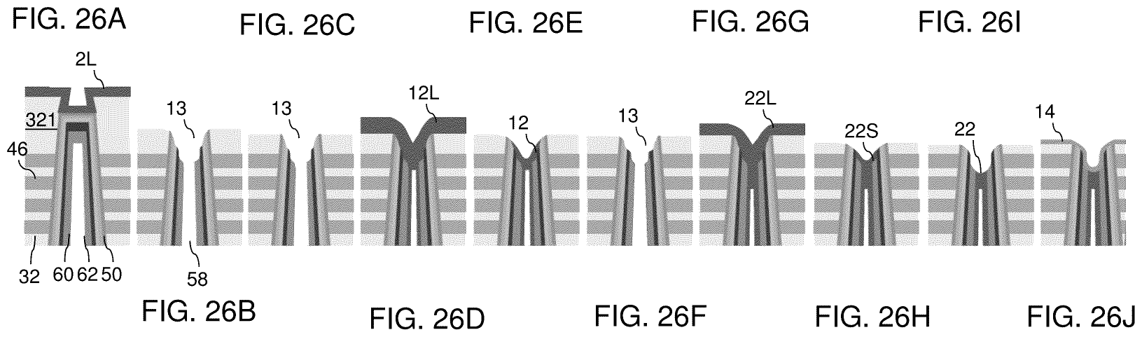

FIGS. 26A-26J are sequential vertical cross-sectional views of a region of a fourth exemplary structure during formation of a source structure according to a fourth embodiment of the present disclosure.

The fourth exemplary structure of FIG. 26A can be derived from the first exemplary structure of FIG. 14A by forming a first spacer insulating material layer 2L in the cavity in place of the insulating material layer 12L shown in FIG. 14A. The first spacer insulating material layer 2L may be a 20 to 50 nm thick silicon oxide layer.

Referring to FIG. 26B, an optional photoresist layer may be formed over the first spacer insulating material layer 2L and patterned to expose portions of the first spacer insulating material layer 2L located over the memory opening fill structures 58. The exposed portions of the first spacer insulating material layer 2L are then removed using reactive ion etching to reopen the cavity 13.

Referring to FIG. 26C, remaining portions of the first spacer insulating material layer 2L may optionally be removed by a dilute hydrofluoric acid etch.

Referring to FIG. 26D, the process step of FIG. 14B may be performed to deposit the insulating material layer 12L into the cavity 13 and over layer 321.

Referring to FIG. 26E, the process step of FIG. 14B may be performed to etch the insulating material layer 12L to form the annular insulating spacers 12.

Referring to FIG. 26F, the annular insulating spacers 12 may be removed by a dilute hydrofluoric acid etch.

Referring to FIG. 26G, a second spacer insulating material layer 22L is formed in the cavity 13 and over layer 321. The second spacer insulating material layer 22L may be a 20 to 50 nm thick silicon oxide layer.

Referring to FIG. 26H, a reactive ion etch (i.e., a sidewall spacer etch) is performed to form second annular insulating spacers 22S and an insulating plug 22 in the cavity 13.

Referring to FIG. 26I, the second annular insulating spacers 22S may be removed by a dilute hydrofluoric acid etch, leaving the insulating plug 22 at the end portion of the cavity.

Referring to FIG. 26J, the interfacial source layer 14 is deposited in the cavity 13 on the insulating plug 22. The primary source layer 16 is then deposited on the interfacial source layer 14 as shown in FIG. 14C.

Referring to all drawings and according to various embodiments of the present disclosure, a memory device is provided, which comprises: an alternating stack (32, 46) of insulating layers 32 and electrically conductive layers 46; a memory opening 49 vertically extending through the alternating stack (32, 46); a memory opening fill structure 58 located in the memory opening 49 and comprising a memory film 50 and a vertical semiconductor channel 60 comprising a first semiconductor material; and a source structure (14, 16) comprising an interfacial source layer 14 and a primary source layer 16. The interfacial source layer 14 comprises a second semiconductor material that has a different band gap from a band gap of the first semiconductor material and is in contact with an end portion of the vertical semiconductor channel 60. The primary source layer 16 comprises a third semiconductor material that has a different band gap from the band gap of the second semiconductor material, and the primary source layer 16 is in contact with the interfacial source layer 14.

In one embodiment, the primary source layer 16 comprises a horizontally-extending portion 16H located over a most proximal insulating layer 321 of the insulating layers 32 of the alternating stack (32, 46). In the first embodiment, the horizontally-extending portion 16H of the primary source layer 16 is vertically spaced from the most proximal insulating layer 321 by a horizontally-extending portion of the interfacial source layer 14 that contacts a horizontal surface of the most proximal insulating layer 321. In the second embodiment, the horizontally-extending portion of the primary source layer 16 is in direct contact with a horizontal surface of the most proximal insulating layer 321, and the horizontally-extending portion 16H of the primary source layer 16 is in direct contact with an annular end surface (i.e., tip) of the vertical semiconductor channel 60.

In one embodiment, the primary source layer 16 comprises a vertically-protruding portion 16P that is located in an end portion of the memory opening 49 and vertically extends at least between a first horizontal plane HP1 including a horizontal interface between a most proximal insulating layer 321 and the source structure (14, 16), and a second horizontal plane including a proximal horizontal surface of a second nearest insulating layer 322 of the insulating layers 32.

In the first and second embodiments, the interfacial source layer 14 is in contact with a cylindrical surface segment of an inner sidewall of the vertical semiconductor channel 60. In the first embodiment, the interfacial source layer 14 is also in contact with an annular end surface of the vertical semiconductor channel 60.

In one embodiment, the first semiconductor material has a first band gap; the second semiconductor material has a second band gap; the third semiconductor material has a third band gap; and the second band gap is narrower than the first band gap and narrower than the third band gap. In one embodiment, the first semiconductor material comprises a first doped silicon material having a doping of a first conductivity type; the second semiconductor material comprises silicon germanium; and the third semiconductor material comprises a second doped silicon material having a doping of the second conductivity type.

In one embodiment, the memory opening fill structure 58 further comprises: a dielectric core 62 that is laterally surrounded by the vertical semiconductor channel 60; and a drain region 63 in contact with another end portion of the vertical semiconductor channel 60 and is vertically spaced from the source structure (14, 16) by the dielectric core 62.

In the third embodiment, the interfacial source layer 14 contacts an end portion of an inner cylindrical sidewall of the memory film 50 and the horizontal surface of the vertical semiconductor channel 60; and the primary source layer 16 is not in direct contact with the memory film 50.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A memory device, comprising:
an alternating stack of insulating layers and electrically conductive layers;
a memory opening vertically extending through the alternating stack;
a memory opening fill structure located in the memory opening and comprising a memory film and a vertical semiconductor channel comprising a first semiconductor material; and
a source structure comprising an interfacial source layer and a primary source layer, wherein the interfacial source layer comprises a second semiconductor material that has a different band gap from a band gap of the first semiconductor material and is in contact with an end portion of the vertical semiconductor channel, and the primary source layer comprises a third semiconductor material that has a different band gap from the band gap of the second semiconductor material, and the primary source layer is in contact with the interfacial source layer.

2. The memory device of claim 1, wherein the primary source layer comprises a horizontally-extending portion located over a most proximal insulating layer of the insulating layers of the alternating stack.

3. The memory device of claim 2, wherein the horizontally-extending portion of the primary source layer is vertically spaced from the most proximal insulating layer by a horizontally-extending portion of the interfacial source layer that contacts a horizontal surface of the most proximal insulating layer.

4. The memory device of claim 2, wherein the horizontally-extending portion of the primary source layer is in direct contact with a horizontal surface of the most proximal insulating layer.

5. The memory device of claim 2, wherein the horizontally-extending portion of the primary source layer is in direct contact with an annular end surface of the vertical semiconductor channel.

6. The memory device of claim 2, wherein the primary source layer further comprises a vertically-protruding portion that is located in an end portion of the memory opening and vertically extends at least between a first horizontal plane including a horizontal interface between the most proximal insulating layer and the source structure and a second horizontal plane including a proximal horizontal surface of a second nearest insulating layer of the insulating layers.

7. The memory device of claim 1, wherein the interfacial source layer is in contact with a cylindrical surface segment of an inner sidewall of the vertical semiconductor channel.

8. The memory device of claim 7, wherein the interfacial source layer is also in contact with an annular end surface of the vertical semiconductor channel.

9. The memory device of claim 1, wherein:
the first semiconductor material has a first band gap;
the second semiconductor material has a second band gap;
the third semiconductor material has a third band gap; and
the second band gap is narrower than the first band gap and narrower than the third band gap.

10. The memory device of claim 9, wherein:
the first semiconductor material comprises a first doped silicon material having a doping of a first conductivity type;
the second semiconductor material comprises a silicon germanium material; and
the third semiconductor material comprises a second doped silicon material having a doping of a second conductivity type opposite to the first conductivity type.

11. The memory device of claim 1, wherein the memory opening fill structure further comprises:
a dielectric core that is laterally surrounded by the vertical semiconductor channel; and
a drain region in contact with another end portion of the vertical semiconductor channel and is vertically spaced from the source structure by the dielectric core.

12. The memory device of claim 1, wherein:
the interfacial source layer contacts an end portion of an inner cylindrical sidewall of the memory film and a horizontal surface of the vertical semiconductor channel; and
the primary source layer is not in direct contact with the memory film.

13. A method of forming a memory device, comprising:
forming an alternating stack of insulating layers and spacer material layers over a carrier substrate, wherein the spacer material layers are formed as or are subsequently replaced with electrically conductive layers;
forming a memory opening through the alternating stack;
forming a memory opening fill structure in the memory opening, wherein the memory opening fill structure comprises a memory film and a vertical semiconductor channel comprising a first semiconductor material having a first band gap;
removing the carrier substrate;
forming a cavity within a volume of the memory opening and exposing a surface of the vertical semiconductor channel from a side of the memory opening from which the carrier substrate is removed;
forming an interfacial source layer comprising a second semiconductor material having a second band gap that is different from the first band gap on an end portion of the vertical semiconductor channel at least in a first portion of the cavity; and
forming a primary source layer comprising a third semiconductor material having a third band gap that is different from the second band gap on the interfacial source layer.

14. The method of claim 13, wherein the primary source layer is formed in a second portion of the cavity and over a horizontally-extending surface of a most proximal insulating layer of the insulating layers.

15. The method of claim 13, wherein:
the memory opening fill structure comprises a sacrificial pillar structure on which the memory film and the vertical semiconductor channel are formed; and
the cavity is formed by removing the sacrificial pillar structure and end portions of the memory film and the vertical semiconductor channel that are proximal to the sacrificial pillar structure.

16. The method of claim 13, wherein:
an end portion of an inner sidewall of the vertical semiconductor channel is physically exposed to the cavity; and
the interfacial source layer is formed directly on the end portion of the inner sidewall of the vertical semiconductor channel.

17. The method of claim 13, wherein:
an end portion of an inner sidewall of the memory film and an annular end surface of the vertical semiconductor channel are physically exposed after formation of the cavity; and
the interfacial source layer is formed directly on the end portion of the inner sidewall of the memory film.

18. The method of claim 13, wherein a horizontally-extending portion of the primary source layer is in direct contact with a tip of the vertical semiconductor channel.

19. The method of claim 13, wherein:
the interfacial source layer contacts an end portion of an inner cylindrical sidewall of the memory film and a horizontal surface of the vertical semiconductor channel; and
the primary source layer is not in direct contact with the memory film.

20. The method of claim 13, wherein:
the first semiconductor material comprises a first doped silicon material having a doping of a first conductivity type;
the second semiconductor material comprises a silicon germanium material; and
the third semiconductor material comprises a second doped silicon material having a doping of a second conductivity type opposite to the first conductivity type.
